(19) United States
(12) Patent Application Publication
(10) Pub. No.: US 2006/0130746 A1
(43) Pub. Date: Jun. 22, 2006

(54) Method for forming nickel silicide film, method for manufacturing semiconductor device, and method for etching nickel silicide

(76) Inventors: Koichi Terashima, Tokyo (JP); Yoshinao Miura, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/544,783

(22) PCT Filed: Feb. 9, 2004
(86) PCT No.: PCT/JP04/01315

§ 371 Date: Aug. 8, 2005

(30) Foreign Application Priority Data
Feb. 7, 2003 (JP) 2003-031110
May 8, 2003 (JP) 2003-129878

(51) Int. Cl. C30B 23/00; C30B 25/00; C30B 28/12; C30B 28/14

(52) U.S. Cl. 117/95; 117/97

(57) ABSTRACT

A method for manufacturing a semiconductor device, which comprises a laminate film forming step of laminating one or more nickel layers and one or more silicon layers alternately on a substrate having, on its surface, a semiconductor region and an insulating film region at a first substrate temperature not causing a silicide forming reaction, a silicide reaction step of subjecting the laminate film to a heat treatment at a second substrate temperature suitable for forming nickel monosilicide, and a step of removing a film having been formed on the insulating film region by wet etching, wherein in the laminate film forming step, the ratio of the number of nickel atoms to that of silicon atoms in the whole laminate film is set to be 1 or more; a method for forming a nickel silicide film which is included in the above method for manufacturing a semiconductor device: and a method for etching a nickel silicide film. The above method allows the formation of a nickel silicide film of a low resistance having a satisfactory thickness with the minimum consumption of silicon atoms in a silicon substrate.

### FIELD OF THE INVENTION

The present invention relates to a nickel silicide formation method, a semiconductor device fabrication method, and a nickel silicide etching method, and, more particularly to a nickel silicide formation method in which the nickel silicide has a sufficient thickness and a low resistivity, a semiconductor device fabrication method using the nickel silicide formation method, and a selective etching method of a nickel silicide film having a nickel-rich composition.

### BACKGROUND OF THE INVENTION

All of patents, patent applications, patent publications, scientific articles and the like, which will hereinafter be cited or identified in the present application, will hereby be incorporated by references in their entirety in order to describe more fully the state of the art, to which the present invention pertains.

Conventionally, a metal silicide which is a chemical compound of metal and silicon has been used as a contact material to a source/drain region and a gate electrode of a silicon MOS transistor. In metal silicides, especially, titanium silicide (TiSi₂) and cobalt silicide (CoSi₂) has been known to have a low resistivity and a low shottky barrier against silicon, thereby currently widely being used for various types of LSI.

In addition, recently, with a progress of miniaturization of a MOS transistor, thereby a progress of thinning of the source/drain region, there has been a movement to use nickel monosilicide (NiSi) for the contact material. This is because of the following reasons. NiSi has a capability of forming a metal silicide film with less silicon atoms than TiSi₂ and CoSi₂ for forming the same thickness film when it is formed by the reaction of silicon atoms of the substrate with the metal atoms deposited on the substrate. Therefore, it becomes possible to decrease a resistance of the silicide film without degrading a junction leak characteristic. In addition, NiSi has another advantage capable of decreasing a process temperature because it can be formed at a lower temperature than that of TiSi₂ and CoSi₂. Accordingly, NiSi has been supposed to be promising as a future contact material.

FIG. 1A to FIG. 1B are partial traverse cross sectional views showing a silicon substrate at each process according to a conventional general formation method of metal silicides. On silicon substrate 51, region 57 is formed, where a dopant concentration is high by, for example, ion implantation. This region 57 corresponds to a source/drain region of a MOS transistor. For forming a metal silicide, as shown in FIG. 1A, first, for example, metal film 52 such as titanium or cobalt is deposited on silicon substrate 51, on which region 57 is formed using, for example, a sputtering method or a molecular beam epitaxy. Next, a metal atom in metal film 52 and a silicon atom of substrate 51 are reacted by annealing the substrate at an appropriate temperature. Through the above-described formation method, metal silicide film 55 shown in FIG. 1B is formed.

Also, a MOS transistor using a metal silicide has been conventionally fabricated with a process called a salicide process. FIG. 2A to FIG. 2D are partial traverse cross sectional views showing a MOS transistor at each process according to a conventional salicide process. First, in FIG. 2A, device isolation region 152, gate insulator film 153, gate electrode 154, gate sidewall 155, source/drain region 156 are formed on silicon substrate 151 using general fabrication processes of a MOS transistor. Device isolation region 152 and gate sidewall 155 are formed with an insulator such as silicon oxide or silicon nitride, and poly silicon is used for gate electrode 154. In addition, source/drain region 156 is formed by ion implanting dopant impurities such as boron and arsenic into silicon substrate 151, and then conducting an activation anneal after that.

Next, as shown in FIG. 2B, metal film 157 such as cobalt and nickel, is deposited on a whole surface of the substrate using, for example, a spattering method.

After that, by annealing the substrate at an appropriate temperature, a metal of the deposited metal film 157, and silicon of source/drain region 156 and gate electrode 154 are reacted to form metal silicide film 158 in FIG. 2C. In this case, since the metal atoms react only at a place where a single crystal silicon of source/drain region 156 or a poly crystal silicon of gate electrode 154 is exposed, the metal atoms on device isolation region 152 and gate sidewall 155 remain as metal film 159 without reaction.

Then, by removing the unreacted metal film 159 using an appropriate etching solution, for example, a mixed solution of sulfuric acid and hydrogen peroxide, metal silicide film 158 can be formed only on source/drain region 156 and gate electrode 154 as shown in FIG. 2D.

As described in the above, according to the conventional metal silicide formation method, silicon atoms in the substrate or the gate electrode are reacted with metal atoms deposited on them.

Recently, on the other hand, for increasing a performance of a MOS transistor, there is a tendency for further thinning a source/drain region. In a silicon MOS transistor, the junction leak characteristic becomes poor as the formed metal silicide approaches to a p-n junction of the source/drain, and if the contact penetrates the source/drain, the transistor does not operate correctly. Therefore, the metal silicide film must be shallower than the source/drain region as shown in FIG. 1B. Since the metal silicide film is formed through a reaction of silicon atoms at source/drain region and metal atoms, the metal silicide film of the contact is also further thinned with a thinning of the source/drain region. However, if the metal silicide film is thinned, a sheet resistance of the metal silicide film increases, thereby resulting in decrease of the performance of the MOS transistor. In addition, if a thickness of the silicide film is increased, a leakage current increases due to approaching of the formed metal silicide film to the p-n junction at the source/drain region, thereby resulting in substantial decrease in transistor performance.

A ratio b/a of a film thickness a of the formed metal silicide to a film thickness b of silicon consumed through a silicide reaction is called as a silicon consumption factor. A value of this consumption factor is different by a kind of metal. Since a consumption factor value of NiSi is small, NiSi has an advantage for thinning die source/drain region. However, it also consumes silicon atoms of the substrate, then, the thinning is limited. Therefore, other method for forming a metal silicide film which consumes less silicon atoms of the substrate, as well as progressing further miniaturization of a transistor, is required.

As one of such a metal silicide formation method, a method in which a nickel silicide (NiSi₂) is grown with epitaxy by a thermal treatment after alternately depositing Ni and Si on a Si substrate has been disclosed in Japanese Laid-open Patent publication No 61-212017. Also, a method for forming NiSi has been disclosed in Japanese Laid-open Patent publication No 8-97420 by conducting a thermal treatment after depositing Ni on silicon to form Ni2Si, and after that, another thermal treatment is conducted again after depositing a poly silicon film on the Ni2Si to form the NiSi. In addition, a method for forming NiSi has been disclosed in U.S. Pat. No. 4,663,191 by depositing Ni and Si simultaneously.

In the conventional methods for forming metal silicide by reacting the metal in a metal film with the substrate silicon as exemplified in the above, when the source/drain region is thinned, it is impossible to obtain a sufficient film thickness of nickel silicide, even if nickel silicide is used, which has a small consumption factor, thereby resulting in substantial consumption of silicon atoms of the substrate silicon. Therefore, a method for forming nickel silicide having small silicon atom consumption of the silicon substrate has been required

However, if the method disclosed in Japanese Laid-open Patent publication No 61-212017 is used, a silicide having nickel disilicide (NiSi₂) is formed as a main composition rather than nickel monosilicide (NiSi). Since the NiSi2 has a high resistivity, this is not suitable for a contact material. In addition, if the method disclosed in Japanese Laid-open Patent publication No 8-97420 is used, nickel is reacted first with silicon substrate to form NiSi₂, then, substantial substrate silicon is consumed in this process. Therefore, there is a limitation for increasing the thickness of NiSi. Also, due to use of salicide process, the above process becomes to be extremely complex. Further, although a salicide process is available for the method disclosed in U.S. Pat. No. 4,663,191, a control of composition ratio between Ni and Si is difficult because of simultaneous deposition of nickel and silicon, and the final product of NiSi2 has a high resistivity, thereby resulting in unsuitable material for the contact material.

As described in the above, it has been difficult to realize a salicide process which is able to form a nickel silicide having a sufficient thickness and a low resistivity, while silicon consumption in silicon substrate is small enough.

### DISCLOSURE OF THE INVENTION

The present invention has been developed for solving the above issues.

It is therefore a first object of the present invention to provide a method for forming a nickel silicide film having a sufficient thickness and a low resistivity, while silicon consumption in silicon substrate is small enough.

It is a second object of the present invention to provide a fabrication method of a semiconductor device using the method for forming the nickel silicide film.

It is a third object of the present invention to provide an etching method of the nickel silicide film which uses a difference of etching characteristic of the nickel silicide film according to a composition ratio of Ni and Si in the film.

According to the first aspect of the present invention for achieving the first object in the above, the present invention provides a nickel silicide film formation method comprising the steps of: a step for forming a stacked layer film by alternately forming at least one nickel layer and at least one silicon layer of an amorphous state on a substrate at a first substrate temperature which does not cause a silicide reaction; and a step of the silicide reaction for forming nickel monosilicide by implementing a thermal treatment of the stacked layer film at a second substrate temperature which causes a nickel monosilicide reaction, wherein, in the step for forming the stacked layer film, a ratio (N_{Ni}/Nₛᵢ) of the number of total nickel atoms (N_{Ni}) to the number of total silicon atoms (Nₛᵢ) existing in a whole stacked layer film is equal to or more than 1.

In the fist aspect of the present invention, since a silicon layer and a nickel layer are alternately formed at least one layer for the each at a substrate temperature which does not cause the silicide reaction, the formed silicon layer is an amorphous state. Nickel atoms preferentially diffuse into an amorphous layer rather than a single crystal silicon layer and a poly crystal silicon layer. Therefore, in the later silicide reaction process, nickel atoms preferentially diffuse into silicon of the amorphous silicon layer to form a nickel silicide film. In addition, since the silicide reaction process is implemented at a temperature to form nickel monosilicide, a formation of nickel disilicide, which has a high resistivity, can be suppressed, and nickel monosilicide having a low resistivity can stably be formed. Further, since the ratio (N_{Ni}/Nₛᵢ) of the number of total nickel atoms (N_{Ni}) to the number of total silicon atoms (Nₛᵢ) existing in the whole stacked layer film is equal to or more than 1, excess silicon atoms necessary for forming nickel disilicide do not exist in the amorphous, silicon layer where nickel atoms preferentially diffuse into, thereby resulting in stably formation of nickel monosilicide, which has a low resistivity. Also, since the silicon layer and the nickel layer are alternately deposited at least one layer for the each, nickel monosilicide having a low resistivity with sufficient thickness can be formed, while suppressing silicon atom consumption consumed for the silicide reaction by adjusting each thickness and number of layers of the silicon layer and the nickel layer.

In the process for forming the stacked layer film, it is favorable to form the stacked layer film so that a ratio of the number of nickel atoms in each nickel layer to the number of silicon atoms in each silicon layer is equal to a ratio of the number of total nickel atoms to the number of total silicon atoms existing in the whole stacked layer film. According to this invention, since the ratio of the number of nickel atoms to the number of silicon atoms in the nickel layer and the silicon layer, which are alternately deposited, is set equal to the ratio of the number of total nickel atoms to the number of total silicon atoms existing in the whole stacked layer film, a uniform nickel monosilicide can be formed through uniform nickel diffusion into the whole stacked layer film during the silicide reaction. As a result, nickel monosilicide, which has a low resistivity, can stably be formed.

In addition, in the stacked layer film formation process, it is favorable to form the stacked layer film so that the ratio (N_{Ni}/Nₛᵢ) of the number of total nickel atoms (N_{Ni}) to the number of total silicon atoms (Nₛᵢ) existing in whole stacked layer film is equal to or more than 1, and equal to or less than 4. According to this invention, a nickel silicide film which is able to suppress silicon atom consumption of the substrate compared with a conventional method can be formed.

Further, it is favorable that the nickel silicide contains the nickel monosilicide equal to or more than 50%. According to this invention, the formed nickel silicide film is preferably applied to the contact of a MOS transistor.

Furthermore, the above-described present invention can be applied to the case where the substrate includes one or more regions of semiconductors selected from a group of single crystal silicon, poly crystal silicon, distorted silicon, single crystal silicon-germanium, poly crystal silicon-germanium, and distorted silicon-germanium at an uppermost surface of the substrate.

According to this invention, since a nickel silicide film is formed through a reaction of nickel and silicon, it is possible to apply this invention to a substrate surface, where the nickel silicide film is formed, other than silicon, for example, single crystal silicon-germanium, poly crystal silicon-germanium, and distorted silicon-germanium. If nickel deposited on silicon-germanium mixed crystal is thermally treated, nickel germanosilicide Ni(Si₁₋ₓGeₓ) is formed. The Ni(Si₁₋ₓGeₓ) has a higher resistivity than NiSi. Then, according to this invention, a film having a lower resistivity can be obtained than the case where silicon-germanium mixed crystal and nickel are reacted. Therefore, it is also possible to increase a transistor performance if silicon-germanium mixed crystal is used for the source/drain region and poly crystal silicon-germanium is used for the gate electrode of a MOS transistor.

In addition, the substrate may be one selected from a group of a silicon substrate, a SOI substrate, and a SGOI substrate. According to this invention, by applying this invention to a silicon on insulator (SOI) substrate and a silicon-germanium on insulator (SGOI) substrate as well as the silicon substrate, an advantage which prevents from degrading a MOS transistor performance due to reaching of the nickel silicide film to a buried oxide film can be obtained.

According to the second aspect of the present invention for achieving the second object in the above, the present invention provides a semiconductor device fabrication method comprising steps of: a step for forming a stacked layer film by alternately forming at least one nickel layer and at least on silicon layer of an amorphous state on at least one semiconductor region and on at least one insulator region on a substrate at a first substrate temperature which does not cause a silicide reaction; a step of the silicide reaction for forming a nickel silicide film containing nickel monosilicide, of which composition is different on the semiconductor region and on the insulator region, by implementing a thermal treatment of the stacked layer film at a second substrate temperature which causes a nickel monosilicide reaction; and an etching step for removing the nickel silicide film on at least one insulator region by etching, wherein, in the step for forming the stacked layer film, a ratio (N_{Ni}/Nₛᵢ) of the number of total nickel atoms (N_{Ni}) to the number of total silicon atoms (Nₛᵢ) existing in the whole stacked layer film is equal to or more than 1.

The second aspect of the present invention is a semiconductor device fabrication method using a nickel silicide film according to the first aspect of the present invention. The effects and advantages are similar to the aboves. According to the second aspect of the present invention, the ratio (N_{Ni}/Nₛᵢ) of the number of total nickel atoms (N_{Ni}) to the number of total silicon atoms (Nₛᵢ) existing in the whole stacked layer film is equal to or more than 1. A typical semiconductor region where silicon is exposed includes a source/drain region and a gate electrode, but not limited to these. A typical insulator region includes a silicon oxide region and a silicon nitride region, but also not limited to these. In the semiconductor region, since excess nickel atoms in the stacked layer film diffuse into the semiconductor region during the silicide reaction, nickel monosilicide is formed at the interface between the stacked layer film and the semiconductor region. On the other hand, in the insulator region, since the excess nickel atoms in the stacked layer film are bard to diffuse, nickel-rich nickel silicide is formed at the interface between the stacked layer film and the insulator region. When the stacked layer film uniformly formed on the semiconductor region and the insulator region is caused the silicide reaction, a composition of the nickel silicide after the silicide reaction changes like the above-described according to a kind of the base of the stacked layer film. Especially, the nickel-rich nickel silicide is easily etched. On the other hand, the nickel monosilicide is hard to etch. The inventor have found this fact and resulted in invention of the present invention. Therefore, according to the present invention, by etching the uniformly formed stacked layer film after the silicide reaction, the nickel silicide film on the insulator, which is nickel-rich, is selectively etched. Then, a fabrication efficiency of a semiconductor device having a nickel monosilicide film can be increased.

In the semiconductor fabrication method of the present invention, it is favorable that the nickel silicide on the semiconductor region and on the insulator region after the silicide reaction becomes nickel monosilicide and nickel-rich nickel silicide, respectively.

According to this invention, it is possible to cause the silicide reaction to the uniformly formed slacked layer film, and after that, to selectively etch only the nickel silicide film on the insulator.

In addition, in the semiconductor fabrication method of the present invention, it is favorable that the semiconductor region includes one or more semiconductors selected from a group of single crystal silicon, poly crystal silicon, distorted silicon, single crystal silicon-germanium, poly crystal silicon-germanium, and distorted silicon-germanium, and it is also favorable that the insulator region is silicon oxide and/or silicon nitride, and, further, it is favorable that the substrate is any one selected from a group of a silicon substrate, a SOI substrate, and a SGOI substrate.

According to this invention, the invention can be applied to forming a contact of a usual MOS transistor which is configured, for example, such that the source/drain layer is single crystal silicon, the gate electrode is poly crystal silicon, and the gate sidewall and device isolation region are silicon oxide or silicon nitride. In addition, by applying the invention to a SOI substrate and a SOI substrate other than a silicon substrate, it is possible to prevent from degrading MOS transistor performance due to reaching of the nickel silicide film to the buried oxide layer.

According to the third aspect of the present invention for achieving the third object in the above, the present invention provides an etching method for etching a nickel-rich region located on an insulator region of a nickel silicide film which is formed on at least one semiconductor region and on at least one insulator region on a substratc and a composition of the nickel silicide film is different between the semiconductor region and the insulator region, wherein a ratio (N_{Ni}/Nₛᵢ) of the number of nickel atoms (N_{Ni}) to the number of silicon atoms (Nₛᵢ) in the nickel-rich region is equal to or more than 1.11.

According to the fourth aspect of the present invention for achieving the third object in the above, the present invention provides an etching, method for etching a nickel-rich region located on an insulator region of a nickel silicide film which is formed on at least one semiconductor region and at least one insulator region on a substrate and a composition of the nickel silicide film is different between the semiconductor region and the insulator region, wherein the nickel-rich region has a diffraction peak of Ni₂Si in X-ray diffraction pattern.

According to the fifth aspect of the present invention for achieving the first object in the above, the present invention provides a nickel silicide formation method comprising steps of: a step for forming a layer structure containing silicon and nickel on at least one semiconductor region and on at least one insulator region on a substrate; and a step of silicide reaction for forming a nickel silicide film of which composition is different on the semiconductor region and the insulator region such that the composition on the insulator region is nickel-rich by implementing a thermal treatment of the layer structure at a second substrate temperature which causes a silicide reaction, wherein, in a nickel-rich region located on the insulator region of the nickel silicide film, a ratio (N_{Ni}/Nₛᵢ) of the number of nickel atoms (N_{Ni}) to the number of silicon atoms (Nₛᵢ) is equal to or more than 1.11.

According to the sixth aspect of the present invention for achieving the first object in the above, the present invention provides a nickel silicide formation method comprising steps of: a step for forming a layer structure containing silicon and nickel on at least one semiconductor region and on at least one insulator region on a substrate; and a step of a silicide reaction for forming a nickel silicide film of which composition is different on the semiconductor region and the insulator region so that the composition on the insulator region is nickel-rich by implementing a thermal treatment of the layer structure at a second substrate temperature which causes a silicide reaction, wherein a nickel-rich region located on the insulator region of the nickel silicide film has a diffraction peak of Ni₂Si in X-ray diffraction pattern.

According to the third to the sixth aspects of the present invention, in the case of (1) the ratio (N_{Ni}/Nₛᵢ) of the number of nickel atoms (N_{Ni}) to the number of silicon atoms (Nₛᵢ) is equal to or more than 1.11, or (2) the nickel silicide film has a diffraction peak of Ni₂Si in X-ray diffraction pattern, the nickel silicide is nickel-rich nickel silicide. The inventors of the present invention have found that nickel-rich nickel silicide is easily etched, and that, nickel monosilicide is hard to etch, thereby resulting in invention of the present invention. Therefore, according to the present invention, since only nickel-rich region on the insulator region of the nickel silicide film can selectively be etched, an efficient etching process can be realized.

In the third to the sixth aspects of the present invention, a region of nickel silicide film located on the semiconductor region is composed of nickel monosilicide, and a region of nickel silicide film located on the insulator region is composed of nickel-rich nickel silicide.

In addition, in the third to the sixth aspects of the present invention, it is favorable that the semiconductor region includes one or more semiconductors selected from a group of single crystal silicon, poly crystal silicon, distorted silicon, single crystal silicon-germanium, poly crystal silicon-germanium, and distorted silicon-germanium, and it is also favorable that the insulator region is silicon oxide and/or silicon nitride.

In addition, in the third to the sixth aspects of the present invention, a nickel monosilicide film can selectively be formed only on various kinds of silicon semiconductors. In addition, for example, this can be applied to a distorted channel MOS transistor which is fabricated on a distorted silicon or a distorted silicon-germanium only on which a silicide contact can be formed efficiently. As a result, by suppressing relaxation of the distortion around the channel region, it is possible to prevent from decreasing performance of the distorted channel MOS transistor, and to sufficiently extract original performance of the distorted channel MOS transistor.

In addition, in the third to the sixth aspects of the present invention, it is favorable that the nickel silicide film is formed by causing the silicide reaction after alternately depositing nickel and silicon, or after co-depositing nickel and silicon.

According to the present invention, a nickel silicide film, which is to be selectively etched, may be a silicide reacted after forming multi-stacked layers, or may be a silicide reacted after co-deposition of nickel and silicon. The etching method of the present invention is, in any cases, can selectively etch only nickel-rich nickel silicide.

Furthermore, it is favorable that the substrate is any one selected from a group of a silicon substrate, a SOI substrate, and a SGOI substrate.

### BRIEF DESCRIPTION OF THE DRAWINGS

FIG. 1A to FIG. 1B are partial traverse cross sectional views showing a silicon substrate at each process according to a conventional general formation method of metal silicides.

FIG. 2A to FIG. 2D are partial traverse cross sectional views showing a MOS transistor at each process according to a conventional salicide process.

FIG. 3A to FIG. 3B are partial traverse cross sectional views showing a substrate at each step relating to formation of a nickel silicide film having nickel monosilicide as a main composition on a silicon substrate.

FIG. 4A and FIG. 4B are, in the second embodiment of the present invention, partial traverse cross sectional views showing a substrate at each process relating to a method for forming a nickel silicide film containing nickel monosilicide as a main composition on a silicon substrate.

FIG. 5A to FIG. 5E are, in the third embodiment of the present invention, partial traverse cross sectional views showing each process relating to a method of nickel silicide film formation when a nickel silicide film is applied to a contact of the source/drain and the gate electrode.

FIG. 6 is a figure showing an example of X-ray diffraction pattern of a nickel silicide film which is formed on Si and SiO₂.

FIG. 7 is a cross sectional TEM photograph of Ni₂Si formed on SiO₂ before etching.

FIG. 8 is a cross sectional TEM photograph of Ni₂Si formed on SiO₂ after etching.

FIG. 9A to FIG. 9D are partial traverse cross sectional views showing each process according to one example of method of the fourth embodiment of the present invention for forming a nickel silicide film containing nickel monosilicide as a main composition on a source/drain region and a gate electrode of a MOS transistor on a silicon substrate with a self-aligning manner.

FIG. 10 is a partial enlarged traverse cross sectional view of a MOS transistor shown in FIG. 9B.

FIG. 11A to FIG. 11B are partial traverse cross sectional views showing each process according to one example of method of the fifth embodiment of the present invention for forming a nickel silicide film containing nickel monosilicide as a main composition on a source/drain region and a gate electrode of a MOS transistor on a silicon substrate with a self-aligning manner.

FIG. 12 is a partial traverse cross sectional view showing a MOS transistor on a SOI substrate, which is formed a nickel silicide film using the sixth embodiment of the present invention with a method similar to that of the above-described fourth and fifth embodiments.

FIG. 13 is a partial traverse cross sectional view showing a MOS transistor formed on a distorted silicon layer using the seventh embodiment of the present invention with a method similar to that of the above-described fourth to sixth embodiments.

FIG. 14A to FIG. 14D are partial traverse cross sectional views showing each process according to one example of method of the eighth embodiment of the present invention for forming a nickel silicide film containing nickel monosilicide as a main composition on a source/drain region and a gate electrode of a MOS transistor on a silicon substrate with a self-aligning manner.

### PREFERRED EMBODIMENTS OF THE PRESENT INVENTION

Embodiments of the present invention will be explained by referring to figures.

(A Nickel Silicide Film Formation Method)

According to a nickel silicide film formation method of the present invention, the method comprises a step for forming a stacked layer film by alternately stacking at least one nickel layer and at least one silicon layer of an amorphous state on a substrate at a first substrate temperature which does not cause a silicide reaction, and a step of the silicide reaction for forming nickel monosilicide by implementing a thermal treatment of the stacked layer film at a second substrate temperature which causes a nickel monosilicide reaction, wherein, in the step for forming the stacked layer film, a ratio (N_{Ni}/Nₛᵢ) of the number of total nickel atoms (N_{Ni}) to the number of total silicon atoms (Nₛᵢ) in the whole stacked layer film being equal to or more than 1 is important.

### First Embodiment

A nickel silicide film formation method in a first embodiment of the present invention will be explained.

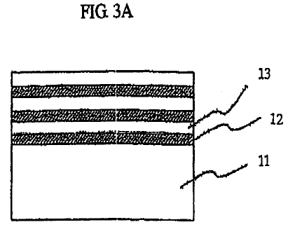

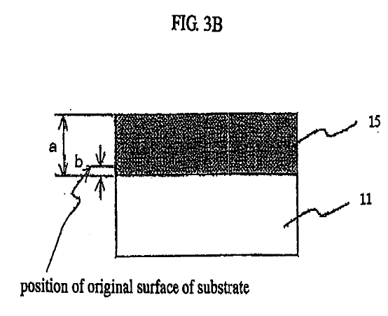

FIG. 3A to FIG. 3B are partial traverse cross sectional views showing a substrate at each step relating to formation of a nickel silicide film having nickel monosilicide as a main composition on a silicon substrate.

In the present invention, nickel silicide film 15 means a nickel silicide film having nickel monosilicide as a main composition. Meanwhile, an example of composition other then the main composition is, for example, nickel atoms, silicon atoms, and nickel disilicide, which are existing in the film without the silicide reaction. Especially, it is favorable that the nickel monosilicide is contained in the nickel silicide film more than 50%, more favorable if the nickel monosilicide is more than 80%, and the most favorable if the nickel monosilicide is more than 90%. The higher the ratio of nickel monosilicide in the nickel silicide film is, the better the film is for a contact material of a MOS transistor. In the present invention, a “main composition” is used as a word for meaning existence of more than 50% of nickel monosilicide in the film.

Regarding silicon substrate 11, it is no matter whether the silicon substrate is single crystal silicon or poly crystal silicon. However, as for the surface orientation, other than a (111) surface, for example, a (100) surface or a slightly declined (100) surface is favorable for a principal surface. The reason is that an epitaxial growth issue of nickel disilicide easily takes place if the (111) surface is employed as the principal surface.

On a surface of silicon substrate 11, a high dopant concentration layer may be formed using ion implantation and with an activation thermal treatment. Also, one or more semiconductor regions selected from a group of distorted silicon, single crystal silicon-germanium, poly crystal silicon-germanium, and distorted silicon-germanium may be included on the uppermost surface of the substrate.

According to the nickel silicide film formation method of the present invention, nickel layer 12 and silicon layer 13 are alternately formed on silicon substrate 11 at the beginning. In FIG. 3A, nickel layer 12, silicon layer 13, nickel layer 12, silicon layer 13, and so on, are deposited in order three layers in total for the each from a side close to silicon substrate 11. Nickel layer 12 and silicon layer 13 are formed by depositing nickel atoms and silicon atoms using optionally, for example, a sputtering method and a molecular beam epitaxy method, respectively

A first substrate temperature, which is a temperature of silicon substrate 11, for forming nickel layer 12 and silicon layer 13 is set at a temperature which does not cause a silicide reaction between the deposited nickel layer 12 and silicon layer 13. Since nickel layer 12 and silicon layer 13 are alternately deposited on a substrate of which temperature is set at the first substrate temperature, the silicide reaction between nickel atoms and silicon atoms does not take place, and in addition, silicon layer 13 can be formed with an amorphous state. The first substrate temperature may arbitrarily be changed by considering deposition conditions, for example, a kind of deposition apparatus to be used and thicknesses of nickel layer and silicon layer. However, regarding a range of the temperature, it is favorable that the range is about 20° C. at room temperature to 200° C. in general, and 50° C.-100° C. is more preferable. The lowest temperature of the range is decided mainly from view point of preventing from adsorbing impurities on the substrate surface from atmosphere.

In the present invention, thicknesses of nickel layer 12 and silicon layer 13 are set such that a ratio (N_{Ni}/Nₛᵢ) of the number of nickel atoms (N_{Ni}) to the number of silicon atoms (Nₛᵢ) in the whole stacked layer film is equal to or more than 1. That is, the thickness of nickel layer 12 and that of silicon layer 13 are set such that a ratio (N_{Ni}:Nₛᵢ) of the number of total nickel atoms to the number of total silicon atoms existing in the whole stacked layer film is 1:1, or nickel is more than silicon. For example, if the ratio is calculated using atomic mass and specific gravity of nickel and silicon, the ratio (N_{Ni}:Nₛᵢ) of the number of total nickel atoms (N_{Ni}) to the number of total silicon atoms (Nₛᵢ) existing in the whole stacked layer film becomes 1:1 when a ratio of the total thickness of the nickel layer to the total thickness of the silicon layer in the whole stacked layer is 1.79. Therefore, 1 or more of the ratio (N_{Ni}/Nₛᵢ) of the number of total nickel atoms (N_{Ni}) to the number of total silicon atoms (Nₛᵢ) existing in the whole stacked layer film can be achieved by making that the ratio of the total thickness of silicon layer to the total thickness of nickel layer in the whole stacked layer is 1.79 or less.

By using the stacked layer film in which the ratio (N_{Ni}:Nₛᵢ) of the number of total nickel atoms to the number of total silicon atoms is controlled to be 1:1, a nickel silicide film containing nickel monosilicide as a main composition, which is uniform and well crystallized, can be formed through complete reaction of nickel atoms in the stacked nickel layer and silicon atoms in the silicon layer with a silicide reaction process which will be described later.

In addition, in the stacked layer film in which the ratio (N_{Ni}:Nₛᵢ) of the number of total nickel atoms to the number of total silicon atoms is controlled to be 1:1, or nickel is more than silicon, there exist excess nickel atoms which were not reacted with silicon atoms in the silicon layer, and the excess nickel atoms react with silicon atoms in the substrate by diffusing into the substrate. However, the excess nickel atoms reacting with silicon atoms in the substrate are the atoms which were not reacted with the stacked silicon layer 13, and the quantity is bit. Therefore, a nickel silicide film containing nickel monosilicide as a main composition, which is uniform and well crystallized, can be formed. By changing thicknesses of nickel layer 12 and silicon layer 13 which are alternately stacked, a thickness of nickel silicide to be formed can also be changed. On the other hand, when the number of silicon atoms in stacked silicon layer 13 is larger than that of nickel atoms in nickel layer 12, excess silicon atoms may remain to be unreacted, and nickel disilicide having a high resistivity may also be formed. As a result, the obtained nickel silicide film becomes not uniform and not well crystallized, and its resistivity becomes high.

If the ratio (N_{Ni}/Nₛᵢ) of the number of total nickel atoms (N_{Ni}) to the number of total silicon atoms (Nₛᵢ) in the whole stacked layer film is much larger than 1, the excess nickel atoms which have not reacted with silicon atoms in the stacked silicon layer react with silicon in the substrate by diffusing into the substrate. Therefore, it is favorable that the ratio (N_{Ni}/Nₛᵢ) of the number of total nickel atoms (N_{Ni}) to the number of total silicon atoms (Nₛᵢ) in the whole stacked layer film is not increased too much for the purpose of the present invention which intends to reduce silicon consumption in the substrate as much as possible.

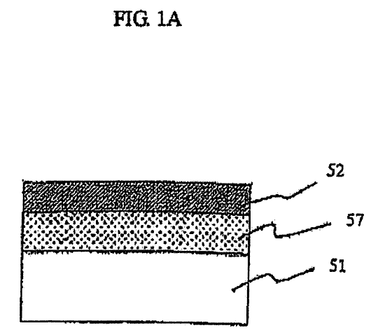

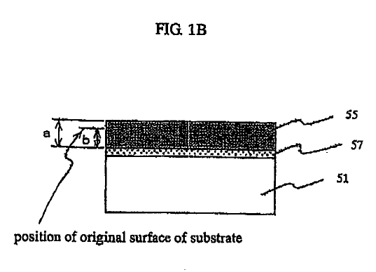

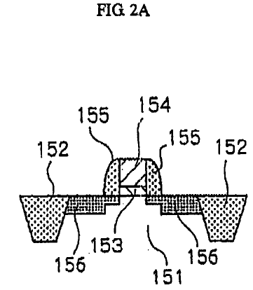

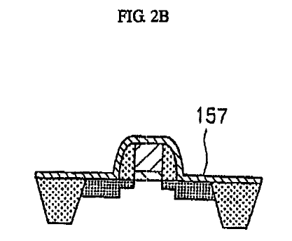

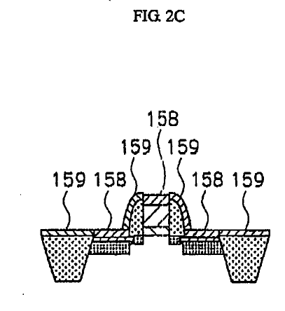

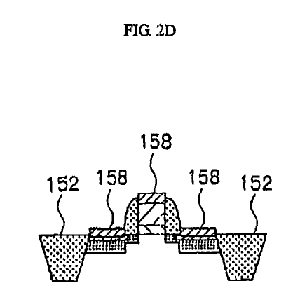

For considering a favorable range of the ratio (N_{Ni}/Nₛᵢ) of the number of total nickel atoms (N_{Ni}) to the number of total silicon atoms (Nₛᵢ) in the whole stacked layer film, for example, a case for forming a nickel silicide film of 10 nm in thickness on the substrate will be examined. A consumption factor of nickel silicide containing nickel monosilicide as a main composition, that is, a ratio (b/a) of a thickness b of silicon consumed by the silicide reaction to a thickness; a of formed nickel silicide film is about 0.82. Then, according to the conventional method shown in FIG. 1A and FIG. 1B, a silicon of about 8 nm in thickness in upper region of the silicon substrate is consumed. On the contrary, according to the embodiment of the present invention shown in FIG. 3A and FIG. 3B, most of nickel atoms in the deposited nickel layer and most of silicon atoms in the deposited silicon layer react completely to form nickel monosilicide. As a result, a quantity of silicon consumption (referred to as symbol b in FIG. 3B) in the silicon substrate is about 4 nm in thickness in upper region of the silicon substrate when the number of total nickel atoms (N_{Ni}):the number of total silicon atoms (Nₛᵢ)=2:1, and about 6 nm in thickness in upper region of the silicon substrate when the number of total nickel atoms (N_{Ni}):the number of total silicon atoms (Nₛᵢ)=4:1, and also about 7 nm in thickness in upper region of the silicon substrate when the number of total nickel atoms (N_{Ni}):the number of total silicon atoms (Nₛᵢ)=5:1. Therefore, if improvement of at least 25% is required compared with the conventional method shown in FIG. 1A and FIG. 1B, it is favorable that the ratio (N_{Ni}/Nₛᵢ) of the number of total nickel atoms (N_{Ni}) to the number of total silicon atoms (Nₛᵢ) existing in the whole stacked layer film is equal to or more than 1, and equal to or less than 4.

In addition, if a region of silicon-germanium mixed crystal layer or a region of poly crystal silicon-germanium layer is included in the uppermost of the substrate surface, it is favorable to form nickel monosilicide by adjusting condition so that a part of nickel atoms in the deposited nickel layer on the substrate reacts with silicon in the substrate. For the above condition, as with the case described in the above for forming nickel silicide film on the silicon substrate, it is favorable that the ratio (N_{Ni}/Nₛᵢ) of the number of total nickel atoms (N_{Ni}) to the number of total silicon atoms (Nₛᵢ) existing in the whole stacked layer film is 1 to 4 by considering the consumption factor.

Through the reaction of the part of nickel atoms in the nickel layer with silicon atoms in the substrate, it is possible to reflect a crystallity of single crystal silicon in the substrate to a crystallity of the formed nickel monosilicide. As a result, a nickel monosilicide film with better crystallity can be obtained. In addition, when a base of the stacked layer film is a silicon layer or a silicon-germanium layer, it is possible to reduce a contact resistance by consuming silicon atoms in the base. To obtain this effect, it is favorable to increase nickel atoms more than that the ratio (N_{Ni}/Nₛᵢ) of the number of total nickel atoms (N_{Ni}) to the number of total silicon atoms (Nₛᵢ) existing in the whole stacked layer film is 1:1. That is, it is favorable to configure that the ratio (N_{Ni}/Nₛᵢ) of the number of total nickel atoms (N_{Ni}) to the number of total silicon atoms (Nₛᵢ) existing in the whole stacked layer film is equal to or more than 1, and equal to or less than 4.

Further, for example, regarding a MOS transistor, a thickness of a source drain layer is becoming thinner with progress of the miniaturization. In this case, it is favorable that the ratio (N_{Ni}/Nₛᵢ) of the number of total nickel atoms (N_{Ni}) to the number of total silicon atoms (Nₛᵢ) existing in the whole stacked layer film is equal to or less than 4. If a consumption factor of 0.61 is required, it can be achieved by configuring that the ratio, (N_{Ni}/Nₛᵢ) of the number of total nickel atoms (N_{Ni}) to the number of total silicon atoms (Nₛᵢ) existing in the whole stacked layer film is equal to or less than 3, and if the consumption factor of 0.41 is required, it can be achieved by configuring that the ratio (N_{Ni}/Nₛᵢ) of the number of total nickel atoms (N_{Ni}) to the number of total silicon atoms (Nₛᵢ) existing in the whole stacked layer film is equal to or less than 2. Also, considering further miniaturization in a future, it is favorable to configure that the ratio (N_{Ni}/Nₛᵢ) of the number of total nickel atoms (N_{Ni}) to the number of total silicon atoms (Nₛᵢ) existing in the whole stacked layer film is equal to or less than 2.

In these stacked layer film formation process, it is favorable that a ratio of the number of nickel atoms (N_{Ni}) in each nickel layer to the number of silicon atoms (Nₛᵢ) in each silicon layer is equal to the ratio (N_{Ni/}Nₛᵢ) of the number of total nickel atoms (N_{Ni}) to the number of total silicon atoms (Nₛᵢ) existing in the whole stacked layer film. To make the ratios equal between the atoms in each layer and that of in the whole stacked layer film is, for example, to configure that a ratio of the number of nickel atoms (N_{Ni}) in one nickel layer to the number of silicon atoms (Nₛᵢ) in one silicon layer is equal to the ratio of the number of total nickel atoms (N_{Ni}) to the number of total silicon atoms (Nₛᵢ) existing in the whole multi-stacked layer film.

By making the configuration like these, a diffusion of nickel during a silicide reaction, which will be described later, is uniformly performed at each portion of the stacked layer film, thereby resulting in easy formation of uniform nickel monosilicide. Accordingly, it becomes possible to stably form a nickel monosilicide having a low resistivity.

In the present invention, it is important that the number of nickel atoms and the number of silicon atoms in the stacked layer film have a relation described in the above, and the film is formed with a condition within the range of the relation. A thickness of a practically formed each nickel layer or silicon layer is in a range of 2 nm˜10 nm in general. For stimulating the silicide reaction by rapidly diffusing nickel atoms into silicon, it is favorable to thin the nickel layer as thin as possible. However, since nickel disilicide is likely to be formed and a long time is needed for the stacking process due to many stacking layers when the nickel layer is too thin, it is favorable that the thickness is set within the above range. The number of stacking layers is decided considering a thickness of a final nickel silicide film to be obtained, that is, a nickel silicide film of 10˜30 nm in thickness is formed in general considering the number of each nickel layer and silicon layer based on each thickness of the layers.

Next, a silicide reaction process will be explained. A nickel silicide film formation method of the present invention is, as described in the above, performed by implementing a thermal treatment at a second substrate temperature which causes a nickel monosilicide formation. As a result, as shown in FIG. 3B, nickel silicide film 15 containing nickel monosilicide as a main composition is obtained. Regarding the method of the thermal treatment, for example, annealing with a common furnace or a rapid thermal anneal (ETA) can be optionally used. As for the second substrate temperature, any temperature can be selected if the nickel monosilicide is stably formed at the temperature. The second substrate temperature is, although it is modified according to a method of the thermal treatment, preferably within a range of 300° C.˜750° C. in general, and 350° C.˜500° C. is more preferable. When the second substrate temperature is higher than 750° C., a nickel silicide film containing nickel disilicide, which has a high resistivity, as a main composition is formed. On the other hand, when the second substrate temperature is lower than 300° C., nickel monosilicide is not always formed due to insufficient silicide reaction.

A preliminary thermal treatment at a low temperature before the thermal treatment at the second substrate temperature may be conducted. In this case, it is favorable that a temperature of the preliminary thermal treatment at a low temperature is lower than the second substrate temperature. If a high temperature is used for the thermal treatment at the beginning, an abnormal high temperature may locally appear, thereby resulting in possibility to cause variations of, such as, a composition and a film thickness of the nickel silicide film. Through the preliminary thermal treatment at a low temperature, a change of crystallity of the nickel layer and the silicon layer composing the stacked layer film is caused without completing the silicide reaction. That is, the nickel layer and the silicon layer are changed from amorphous states to more crystalline states. Conducting the thermal treatment at the second substrate temperature after that, a gradient of temperature rise is reduced, as a result, it becomes possible to stably form the nickel silicide film without causing variations of such as the composition and the film thickness.

Regarding an atmosphere during the thermal treatment, vacuum or arbitrary gas atmosphere, for example, gas atmosphere such as nitrogen may be used. However, it is favorable that the atmosphere does not contain oxygen as possible as it can for not to oxidize the stacked nickel layer and the silicon layer. In addition, a time for the thermal treatment is decided considering a total thickness of the stacked layer film, a method of the thermal treatment, and a temperature of the thermal treatment. The time is 5˜60 minutes for the thermal treatment with a common furnace, and 10˜120 seconds for the RTA.

By conducting the above thermal treatment, nickel monosilicide is formed through a reaction of nickel atoms in nickel layer 12 with silicon atoms by diffusing the nickel atoms into silicon layer 13. In this process, a part of nickel atoms in nickel layer 12 nearest to substrate 11 also diffuses into silicon substrate 11. However, since the upper silicon layer 13 adjacent to nickel layer 12 is made of amorphous silicon as contrasted with crystal silicon of silicon substrate 11, nickel atoms preferentially diffuse into the upper amorphous silicon to form nickel monosilicide.

In addition, by forming a stacked layer film such that a ratio (N_{Ni}/Nₛᵢ) of the number of total nickel atoms (N_{Ni}) to the number of total silicon atoms (Nₛᵢ) existing in the whole stacked layer film is 1:1 or nickel is more than silicon, nickel atoms are left even if silicon atoms in silicon layer 13 are completely changed into nickel monosilicide. The extra nickel atoms also form nickel monosilicide by diffusing into silicon substrate 11, thereby reacting with silicon in the substrate.

Accordingly, in the present embodiment, as shown in FIG. 3B, a thickness b which is the consumed thickness of silicon substrate 11 through the reaction can be made very small against a thickness a of the nickel silicide film containing the formed nickel monosilicide as a main composition. Nickel silicide film 15 obtained through the above has a good uniformity and a good crystallity.

Furthermore, in the present embodiment, by reversing a stacking order of the nickel layer and the silicon layer, the silicon layer can be formed at a nearest layer to the substrate, next, the nickel layer on it, and the next, the silicon layer, and so on in order. In the above configuration, nickel atoms in the nickel layer must pass through the amorphous silicon layer before reaching to the silicon substrate. As a result, nickel monosilicide can be stably formed even if the ratio (N_{Ni}/Nₛᵢ) of the number of total nickel atoms (N_{Ni}) to the number of total silicon atoms (Nₛᵢ) existing in the whole stacked layer film is just 1:1. In this case, it is possible to make the silicon consumption of silicon substrate zero. However, by forming a stacked layer film such that the ratio (N_{Ni}/Nₛᵢ) of the number of total nickel atoms (N_{Ni}) to the number of total silicon atoms (Nₛᵢ) existing in the whole stacked layer film is 1:1 or nickel is more than silicon, thereby forming a nickel silicide film composed of nickel monosilicide with a condition so that a part of nickel atoms react with silicon in the silicon substrate, a better crystalline nickel silicide film can be obtained due to reflection of crystallity of single crystal silicon in the substrate to the crystallity of the formed nickel monosilicide.

As described before, according to the present embodiment, after forming a stacked layer film which stacks a nickel layer and a silicon layer, a nickel silicide film is formed through a silicide reaction. However, instead of forming a stacked layer film, the nickel silicide film may also be formed by causing the silicide reaction after co-depositing nickel and silicon. In this case, a composition ratio. (N_{Ni}/Nₛᵢ) of the number of nickel and silicon atoms during the film formation is set, as described in the above, to be more than 1. The co-deposited film through the above process is reacted through the silicide reaction by conducting a thermal treatment at the second substrate temperature described before. Regarding a co-deposition method of nickel and silicon, various film formation methods such as a reactive spattering method and a CVD method may be applied.

Meanwhile, regarding the crystal orientation of the substrate surface on which nickel silicide is formed, it has been already mentioned. A (100) surface or a slightly declined (100) surface is favorable for the orientation.

In addition, in the present embodiment, the substrate may be a silicon on insulator (SOI) substrate or a silicon-germanium on insulator (SGOI) substrate. In this case, when a MOS transistor is fabricated on a thin SOI or SGOI layer, degradation of the MOS transistor characteristic which is caused by reaching of the nickel silicide film, which contains nickel monosilicide as a main composition, to the buried oxide layer can be prevented.

### Second Embodiment

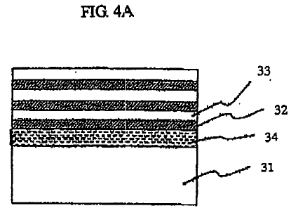

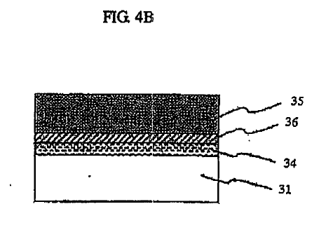

Next, a second embodiment of the instant application will be explained. FIG. 4A and FIG. 4B are, in the second embodiment of the present invention, partial traverse cross sectional views showing a substrate at each process relating to a method for forming a nickel silicide film containing nickel monosilicide as a main composition on a silicon substrate. The second embodiment is an example of a substrate in which a silicon-germanium mixed crystal layer 34 is formed on a surface of silicon substrate 31 in a nickel silicide formation method of the present invention.

As shown in FIG. 4A, as with the method of the first embodiment, nickel layer 32 and silicon layer 33 are alternately formed on the silicon-germanium mixed crystal layer 34 at the beginning at a first substrate temperature which does not cause silicide reaction. In this second embodiment, the first substrate temperature, at which nickel layer 32 and silicon layer 33 are formed, is set in a range of room temperature (about 20° C. in usual)˜200° C. which does not cause the silicide reaction. As a result, silicon layer 33 becomes an amorphous state, and also nickel, and silicon and silicon-germanium mixed crystal do not react to each other during the deposition. In addition, as with the first embodiment, it is favorable that the thicknesses of nickel layer 32 and silicon layer 33 are configured so that a ratio (N_{Ni}/Nₛᵢ) of the number of total nickel atoms (N_{Ni}) to the number of total silicon atoms (Nₛᵢ) existing in the whole stacked layer film is 1:1, or nickel is more than silicon. A thickness of each nickel layer 32 and each silicon layer 33, and the number of nickel layer 32 and silicon layer 33 are arranged considering a thickness of nickel silicide film 35 to be formed.

Next, by implementing a thermal treatment at the second substrate temperature which mainly forms nickel monosilicide, as shown in FIG. 4B, nickel silicide film 35 containing nickel monosilicide as a main composition can be obtained. In this case, since a part of nickel atoms in nickel layer 32 diffuses into silicon-germanium mixed crystal layer 34 and reacts with it, nickel germanosilicide (NiSi_{I-x}Geₓ) layer 36 which has a high resistivity is formed between nickel silicide film 35, which contains nickel monosilicide as a main composition, and silicon-germanium mixed crystal layer 34. Therefore, according to the present embodiment, there is another advantage for obtaining a layer which has a lower resistivity than that obtained from the reaction between silicon-germanium mixed crystal and nickel. Then, the transistor performance can be increased by using the silicon-germanium mixed crystal in source/drain region of a MOS transistor in some case, and by forming the gate electrode with silicon-germanium mixed crystal in other case.

Meanwhile, regarding the thermal treatment at the second substrate temperature, it is favorable that the thermal treatment is implemented in a temperature range of 300° C.˜750° C., and more favorably, 350° C. 500° C., so as to form nickel monosilicide well and not to cause a nickel disilicide reaction.

In the conventional thermal treatment method in which only nickel is deposited, the all formed film become nickel germanosilicide, and it is likely to form defects at the interface between the nickel germanosilicide layer and the silicon-germanium mixed crystal layer due to germanium precipitation. However, in the present embodiment, it is possible to extremely thin the nickel germanosilicide layer to be formed because nickel atoms easily diffuse into the amorphous silicon layer. For example, if a nickel silicide film of 10 nm in thickness is formed under a condition that the ratio (N_{Ni}/Nₛᵢ) of the number of total nickel atoms (N_{Ni}) to the number of total silicon atoms (Nₛᵢ) existing in the whole stacked layer film is 2:1, the nickel germanosilicide layer may be thinned to about 4 nm. Since a resistivity of nickel germanosilicide becomes higher with increase of germanium concentration, according to the present embodiment, a film having a lower resistivity than that of the film formed with the conventional method, where the thermal treatment is implemented after only nickel deposition, can be obtained. In addition, during the thermal treatment, diffusion of germanium atoms in nickel germanosilicide layer takes place. As a result, the germanium concentration in the nickel germanosilicide layer becomes lower, resulting in further lowering of the resistivity.

Further, it is possible to form a silicon layer as a nearest layer to the substrate by reversing the deposition order of the nickel layer and the silicon layer. This is the same with the first embodiment.

In the present embodiment, a nickel silicide formation method of the present invention has been applied to the case where a silicon-germanium mixed crystal layer is formed on a surface of the silicon substrate. However, it is also possible to apply the method to the case where a poly crystal layer is formed on a silicon substrate surface. The reason is that, the silicon layer which is alternately stacked with the nickel layer has an amorphous state, and nickel atoms easily diffuse into the amorphous rather than the crystal. Therefore, according to the present invention, it is possible to form a nickel monosilicide film having a sufficient thickness even if the substrate surface is made of a poly silicon or a poly silicon-germanium with a small consumption of silicon or silicon-germanium of the substrate.

In addition, in the second embodiment of the present invention, the substrate may be not only a usual silicon substrate but also a silicon on insulator (SOI) substrate or a silicon-germanium on insulator (SGOI) substrate. In this case, it is possible to prevent from degrading a MOS transistor performance which is caused by reaching of nickel silicide containing nickel monosilicide as a main composition to the buried oxide layer when the MOS transistor is fabricated on a thin SOI or SGOI layer.

Also, as explained in the first embodiment, instead of forming a nickel layer and a silicon layer, a co-deposition layer of nickel and silicon may be used for forming a nickel silicide film through a silicide reaction after the deposition.

Furthermore, as explained in the first embodiment, it may be possible to implement a preliminary thermal treatment of which temperature is lower than the second substrate temperature before implementing the second thermal treatment.

### Third Embodiment

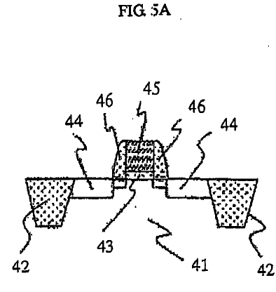

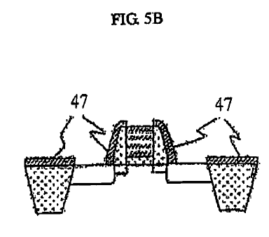

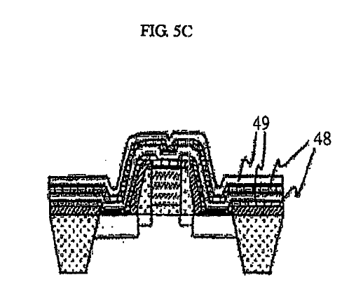

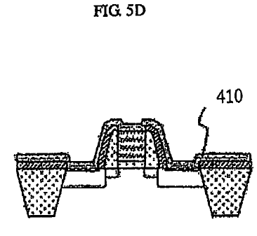

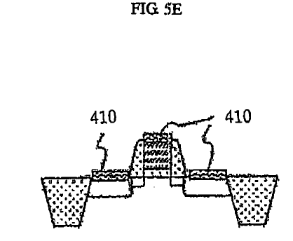

Next, a third embodiment of the present invention will be explained. FIG. 5A to FIG. 5E are, in the third embodiment of the present invention, partial traverse cross sectional views showing each process relating to a nickel silicide film formation method when a nickel silicide film is applied to a contact of a source/drain and a gate electrode. FIG. 5A is a partial traverse cross sectional view of a MOS transistor before forming the contact of nickel silicide. Device isolation region 42, gate insulator film 43, source/drain region 44, gate electrode 45, and gate sidewall 46 are formed on silicon substrate 41.

As shown in FIG. 5B, exposure and etching are conducted using masks after coating a resist on a whole surface, and resist 47 is left only on the device isolation region and the gate sidewall. Next, as shown in FIG. 5C, as with the first and second embodiments, nickel layer 48 and silicon layer 49 are alternately deposited. In this process, a stacked layer structure of nickel and silicon is formed on the whole substrate using, for example, a usual sputtering method or a molecular beam epitaxy method.

Next, by implementing a thermal treatment similar to the first and second embodiments, as shown in FIG. 5D, nickel silicide film 410 is formed. After that, using an etchant which has an etching selectivity against the resist, the nickel silicide film formed on the gate sidewall and the device isolation region is removed together with the resist for fabricating a MOS transistor which is formed nickel silicide contacts on the source/drain region and the gate electrode as shown in FIG. 5E.

A MOS transistor fabricated through the above process is able to reduce a contact resistance because it has a contact of nickel silicide film having a sufficient thickness, thereby resulting in increase in transistor performance. In addition, since the silicide film is formed without consuming substantial silicon at the source/drain region, a distance between the p-n junction at the source/drain region and the silicide film is large enough. Then, a degradation due to junction leakage is few.

(A Fabrication Method of a Semiconductor Device)

Next, a fabrication method of a semiconductor device will be explained.

The fabrication method of a semiconductor device according to the present invention, which uses a nickel silicide film formation method described in the above, comprises a stacked film formation process for alternately stacking at least one nickel layer and at least one silicon layer on a substrate having a semiconductor region and an insulator film region on a surface of the substrate at a first substrate temperature which does not cause a silicide reaction, a silicide reaction process for conducting a thermal treatment of the stacked layer film at a second substrate temperature which causes a formation of nickel monosilicide, and an etching process for removing a film formed on the insulator film by etching, wherein, in the stacked film formation process, a ratio (N_{Ni}Nₛᵢ) of the number of total nickel atoms (N_{Ni}) to the number of total silicon atoms (Nₛᵢ) in the whole stacked layer film is equal to or more than 1.

In the present invention, the each process may be one of a continuous process in some case, and may be an independent process to each other in other case.

In the fabrication method of the present invention, a fundamental feature of the nickel silicide film formed through the stacked film formation process and the silicide reaction process is the same with what is described in the explanation of the nickel silicide formation method. However, the features of the present invention are to alternately deposit a nickel layer and a silicon layer on the semiconductor region and the insulator region on the substrate so that the ratio (N_{Ni}/Nₛᵢ) of the number of total nickel atoms (N_{Ni}) to the number of total silicon atoms (Nₛᵢ) in the whole stacked layer film is equal to or more than 1, and to have a different composition of the nickel silicide film on the semiconductor region and the insulator region after the silicide reaction. A nickel silicide film formed on the insulator region is easily etched due to rich of nickel, as a result, a nickel rich region of the nickel silicide film on the insulator region can be selectively etched with ease.

That is, although silicide is formed though the reaction of nickel and silicon deposited on a substrate where the insulator is exposed, the nickel can not diffuse into the insulator, thereby does not react with atoms composing the insulator. Therefore, on the insulator, nickel silicide having a composition ratio of nickel and silicon corresponding to a ratio of the number of the deposited nickel atoms and silicon atoms is formed. In the present invention, since the deposition is conducted so that the number of nickel atoms is larger than that of silicon atoms, nickel-rich nickel silicide is formed on the insulator region. On the other hand, on the semiconductor region of silicon region, since a part of the deposited nickel atoms diffuse into the substrate and react with silicon atoms in the substrate, the formed nickel silicide film is crystallized by succeeding a crystallity of single crystal silicon or poly crystal silicon of the substrate, and has a grain size with a certain level having a specific orientation. On the other hand, on the insulator region, since the insulator is an amorphous state, the nickel silicide film has a small grain size and no specific crystal orientation, thereby resulting in bad crystallity.

A nickel silicide film having excess nickel atoms and bad crystallity can easily be removed with, for example, an etchant which is prepared by mixing hydrocloric acid, hydrogen peroxide, and water at some ratio. In this case, since the nickel silicide film on silicon has nickel monosilicide (NiSi) as a main composition and a good crystallity, the film is etched little.

Therefore, according to the present invention, it is possible to form a nickel silicide film having a sufficient thickness and low resistivity, as well as suppressing consumption of silicon atoms in the silicon substrate as much as possible. In addition, it is also possible to form a nickel silicide film only on single crystal or poly crystal silicon by removing the nickel silicide film formed on the insulator region by wet etching. If the method of the present invention is applied to a fabrication process of a MOS transistor, a salicide process, which forms nickel silicide only on single crystal silicon of a source/drain region and poly crystal silicon of a gate electrode, can be employed by removing nickel silicide on a silicon oxide film or a silicon nitride film of the device isolation region and the gate sidewall by wet etching.

Regarding the nickel silicide film to be etched, it is favorable that the ratio (N_{Ni}/Nₛᵢ) of the number of total nickel atoms (N_{Ni}) to the number of total silicon atoms (Nₛᵢ) in the whole region is equal to or more than 1.11 (Ni:Si=1:less than 0.9), 1.25 (Ni:Si=1:less than 0.8) is more favorable, and 1.43 (Ni:Si=1:less than 0.70) is further favorable. Nickel silicide films having the above compositions are easily etched by the etchant. This is quite different from the fact that, for example, a nickel silicide film having a ratio (N_{Ni}/Nₛᵢ) of 1.00 (Ni:Si=1:1) is not etched.

The above-described composition may be a composition of entire nickel silicide film, or may be a composition at an interface adjacent to the insulator region. That is, at least the composition at the interface adjacent to the insulator region must be within the range, and the nickel silicide film is etched at least at the interface by erosion of the etchant. Nickel and silicon compositions in the above are results of analysis, for example, with X-ray Photoelectron Spectroscopy (XPS)

The silicide film is etched most favorably when the X-ray diffraction pattern has a diffraction peak of Ni2Si.

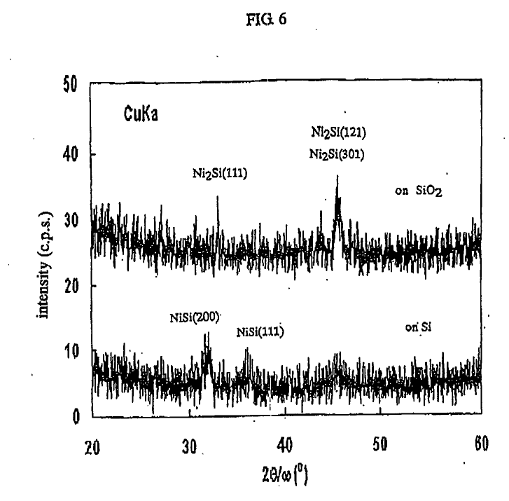

FIG. 6 is a figure showing a X-ray diffraction pattern of a nickel silicide film which is formed on Si composing a semiconductor region and on SiO2 composing an insulator region with a condition that the ratio (N_{Ni}/Nₛᵢ) of the number of total nickel atoms (N_{Ni}) to the number of total silicon atoms (Nₛᵢ) in the whole stacked layer film is 2 (Ni:Si=1:0.5), and implemented the silicide reaction after that with annealing at 400° C.

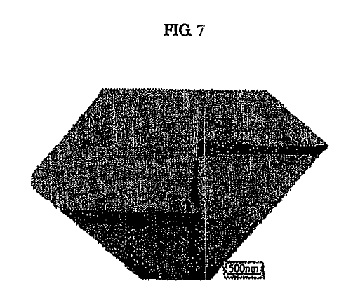

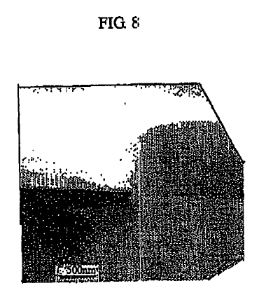

A diffraction peak of nickel monosilicide (NiSi) can be seen on the Si. On the other hand, a diffraction peak of NiSi2 is seen on the SiO2. Inventors of the present invention have confirmed that when a silicide film having the above diffraction pattern was etched, a silicide on SiO2 having a diffraction peak of Ni2Si had been selectively etched. TEM photographs before and after the etching are shown in FIG. 7 and FIG. 8. That is, FIG. 7 is a cross sectional. TEM photograph of Ni2Si formed on SiO2 before the etching. FIG. 8 is a cross sectional TEM photograph of Ni2Si formed on SiO2 after the etching. From FIG. 8, it has been confirmed that the Ni2Si formed on SiO2 had disappeared by the etching.

In addition, as explained in the first embodiment, a nickel silicide film may be formed by causing the above-described silicide reaction after co-deposition of nickel and silicon. In this case, a compositional ratio (N_{Ni}/Nₛᵢ) of nickel and silicon at the deposition is equal to or more than 1 as with the above. A film formed through the above co-deposition is caused the silicide reaction by implementing a thermal treatment at the second substrate temperature described in the above. It was found that the film after the silicide reaction becomes as follows. (i) A nickel silicide film on Si composing a semiconductor region has become a nickel monosilicide film, which is unable to be etched, since the excess nickel atoms are consumed by diffusing into silicon. (ii) A nickel silicide film on SiO2 composing an insulator region has become a Ni2Si film, which is easily etched, since the excess nickel atoms can not diffuse into SiO2. As a result, as described before, a nickel silicide film only on SiO2 of insulator film can be selectively etched. Regarding a method for co-deposition of nickel and silicon, various deposition methods, for example, a reactive spattering method or a CVD method may be adopted.

Further, as explained in the first embodiment, a preliminary thermal treatment at a low temperature may be implemented before the thermal treatment at the second substrate temperature. It is favorable that a temperature of the preliminary thermal treatment is lower than that of a range of the second substrate temperature. If a high temperature thermal treatment is suddenly implemented at the beginning, there is a possibility to cause variations of, for example, composition and thickness of the nickel silicide film due to locally abnormal temperature rise. However, by implementing the preliminary thermal treatment at a low temperature, a change of crystallity of the nickel and silicon layers composing the stacked layer film is caused without causing complete silicide reaction. That is, the nickel layer and the silicon layer are changed from the amorphous state to a higher crystalline state. Also, when silicon and nickel are co-deposited to form a co-deposited film containing silicon and nickel, the co-deposited film is also changed from the amorphous state to a higher crystalline state.

In the present embodiment, the stacked layer film or the co-deposited film is formed on a surface of the semiconductor region and the insulator region. The semiconductor region has a higher crystallity than the insulator region in general. Typically, the insulator region is an amorphous state, on the other hand, the semiconductor region is a crystalline state. The stacked layer film or the co-deposited film is an amorphous state. By implementing the preliminary thermal treatment, the stacked layer film or the co-deposited film is changed from the amorphous state to a higher crystalline state. The change on the semiconductor region is more remarkable than that on the insulator region. That is, since a crystallity of the semiconductor region is higher than that of the insulator region, a difference of the crystallity between these two regions which compose the base of the film effects to the change from the amorphous state to the higher crystalline state of the stacked layer film or the co-deposited film. That is, a stacked layer film or a co-deposited film located on a semiconductor region which has a higher crystallity becomes a high crystalline state by receiving effect of the base having a high crystallity. On the other hand, a part of stacked layer film or a co-deposited film located on an insulator region having a low crystallity becomes a low crystalline state by receiving the effect of the base having a low crystallity. For example, a region of a stacked layer film or a co-deposited film located on a semiconductor region of a single crystal state becomes a single crystal state or a state close to a single crystal state by conducting a preliminary thermal treatment at a lower temperature than the range of the second substrate temperature. On the other hand, a region of a stacked layer film or a co-deposited film located on an insulator region of an amorphous state does not change from the amorphous state, or changes little from the amorphous state. Therefore, the stacked layer film or the co-deposited film conducted the preliminary thermal treatment has a high crystallity on the semiconductor region and a low crystallity on the insulator region.

Then, as already explained in the present embodiment, by implementing the thermal treatment at the second substrate temperature, the silicide reaction is caused to form a nickel silicide film. After that, as explained in the above, by removing a nickel rich region on the insulator region through selective etching, a nickel silicide film composed of only nickel monosilicide area on the semiconductor region can be formed with a self-aligning manner.

A nickel silicide film can be formed with a self-aligning manner even if the etching process is implemented before the silicide reaction process. As described before, a stacked layer film or a co-deposited film implemented the preliminary thermal treatment has a higher crystallity on the semiconductor region and a lower crystallity on the insulator region. The difference of the crystallity has an effect on etching rate. That is, a higher crstallity region has a lower etching rate than a lower crystallity region. Using this fact, by dipping the entire stacked layer film or the co-deposited film in the etchant, only the lower crystallity region located on the insulator region is selectively etched, while leaving the higher crstallity region on the semiconductor region. As a result, the etching can be achieved with a self-aligning manner. After that, by implementing a thermal treatment at the second substrate temperature, thereby causing the silicide reaction of the stacked layer film or the co-deposited film remained on the semiconductor region, the nickel silicide film can be formed with a self-aligning manner only on the semiconductor region.

As described before, an additional advantage of implementing the preliminary thermal treatment at a low temperature is to slow down the temperature rise. As a result, a nickel silicide film can stably be formed without causing variations of, such as, composition and thickness of the film.

### Fourth Embodiment

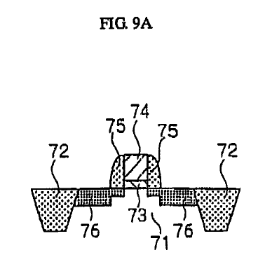

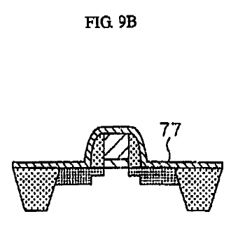

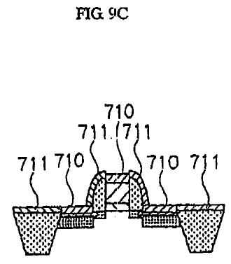

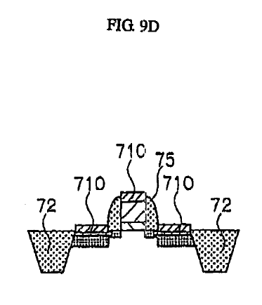

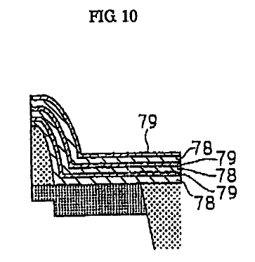

Next, a semiconductor device fabrication method of a fourth embodiment of the present invention will be explained. FIG. 9A to FIG. 9D are partial traverse cross sectional views showing each process according to one example of method of the fourth embodiment of the present invention for forming a nickel silicide film containing nickel monosilicide as a main composition on a source/drain region and on a gate electrode of a MOS transistor on a silicon substrate with a self-aligning manner. FIG. 10 is a partial enlarged traverse cross sectional view of a MOS transistor shown in FIG. 9B. In this embodiment, as with the above embodiments, a nickel monosilicide film means a nickel silicide film containing nickel monosilicide as a main composition.

First, as shown in FIG. 9A, device isolation region 72, gate insulator film 73, gate electrode 74, gate sidewall 75, and source/drain region 76 are formed on silicon substrate 71 with a usual fabrication process of a MOS transistor. In the figure, device isolation region 72 and gate sidewall 75 are formed with an insulator film such as a silicon oxide film and a silicon nitride film, and poly crystal silicon is used for gate electrode 74. Further, source/drain region 76 is formed by ion implantation of dopant impurity such as boron or arsenic into substrate silicon 7, followed by an activation anneal.

Next, as shown in FIG. 9B and FIG. 10, stacked layer film 77 alternately stacking nickel layer 78 and silicon layer 79 on the entire substrate is formed. FIG. 10 is an enlarged figure of stacked layer film 77. Nickel layer 78 is formed first on the substrate and silicon layer 79 is formed next. Three sets of nickel layer 78 and silicon layer 79 are stacked on the substrate. Nickel layer 78 and silicon layer 79 can be formed by depositing nickel atoms and silicon atoms using optionally, for example, a spattering method or a molecular beam epitaxy method. However, a substrate temperature during the deposition must be maintained at less than 200 C so that silicon layer 79 becomes amorphous silicon, and also nickel and silicon do not react during the deposition.

Regarding the thicknesses of nickel layer 78 and silicon layer 79, they must be controlled so that a ratio (N_{Ni}/Nₛᵢ) of the number of total nickel atoms (N_{Ni}) to the number of total silicon atoms (Nₛᵢ) in the whole stacked layer film 77 is equal to or more than 1. In other words, N_{Ni}:Nₛᵢ must be 1:less than 1. Deposition forms of the nickel layer and the silicon layer are similar to those of described in explanation of the nickel silicide film formation method. When a ratio of a total silicon layer thickness to a total nickel layer thickness is 1.79, the ratio (N_{Ni}/Nₛᵢ) of the number of total nickel atoms (N_{Ni}) to the number of total silicon atoms (Nₛᵢ) in the whole stacked layer film 77 is equal to 1. Then, if the number of nickel atoms larger than that of silicon atoms is required, it can be achieved by making the ratio of the total silicon layer thickness to the total nickel layer thickness is less than 1.79.

Regarding the order of stacking of a nickel layer and a silicon layer, the silicon layer may be deposited at the nearest layer to the substrate by reversing the order of the stacking. If the silicon layer is deposited at the upper most layer, it is possible to prevent from oxidizing the deposited nickel layer during a time between taking out the substrate out of the apparatus after deposition and implementing the thermal treatment.

Next, as shown in FIG. 9C, nickel monosilicide film 710 is formed on a source/drain region and on a gate electrode, both of where silicon is exposed, by implementing a thermal treatment at a second temperature which is higher than that of a substrate temperature when nickel and silicon are deposited. The thermal treatment method, the temperature and the atmosphere of the thermal treatment are similar to those of the method of the above-described nickel silicide film formation method, then, the explanations are omitted.

In the present embodiment, a nickel monosilicide film is formed through the reaction of the deposited nickel atoms and silicon atoms. In this case, in the source/drain region and the gate electrode where silicon is exposed, since the number of nickel atoms is larger than that of silicon atoms, thereby existing sufficient excess nickel atoms more than necessary for forming nickel monosilicide, nickel monosilicide is formed by causing the silicide reaction through diffusion of a part of the excess nickel atoms into the exposed silicon. On the other hand, if the number of deposited silicon atoms is larger than that of nickel atoms, for example, the excess silicon atoms are left without reaction in some case, or nickel disilicide is formed in other case. Then, the obtained nickel silicide film becomes non-uniform, and has a poor crystallity and a high resistivity. Therefore, in the present invention, the nickel layer and the silicon layer are deposited so that a ratio (N_{Ni}/N_{Si}) of the number of total nickel atoms (N_{Ni}) to the number of total silicon atoms (Nₛᵢ) existing in the whole stacked layer film becomes equal to or more than 1, in other words, N_{Ni}:Nₛᵢ becomes 1:less than 1. Accordingly, the excess nickel atoms diffuse into the substrate silicon and react with it to form a nickel silicide film containing uniform and higher crystalline nickel monosilicide as a main composition. In this case, nickel atoms which react with the substrate silicon are ones left without reaction with the deposited silicon atoms.

On the other hand, as shown in FIG. 9C, nickel and silicon deposited on a device isolation region and a gate sidewall where an insulator film is exposed also react to form nickel silicide film 711. However, since the nickel does not react with atoms composing the insulator film, nickel silicide having a composition corresponding to the ratio of the number of deposited nickel atoms and that of silicon atoms is formed on the insulator film. In the present invention, as described in the above, the deposition is implemented so that the number of nickel atoms are larger than that of silicon atoms, then, nickel-rich nickel silicide is formed on the insulator film. In addition, on the silicon region, since a part of the deposited nickel atoms react with silicon atoms in the substrate, the formed nickel silicide film is crystallized by succeeding a crystallity of single crystal silicon or poly crystal silicon of the substrate, and has a grain size with a certain level having a specific orientation. On the other hand, on the insulator region, since the insulator is an amorphous state, the nickel silicide film has a small grain size and no specific crystal orientation, thereby resulting in a poor crystallity. Such a nickel silicide film which is nickel-rich and has a poor crystallity is easily removed by an appropriate etchant. In this case, a nickel silicide film on silicon has nickel monosilicide as a main composition and a good crystallity. Then, the film is etched little.

Therefore, by dipping the whole substrate after the thermal treatment in an appropriate etchant, for example, a mixture of hydrochloric acid:hydrogen peroxide solution:water 1:1:6, as shown in FIG. 9D, a structure having nickel silicide, only on the source drain region and the gate electrode part can be formed by removing the film formed on the insulator film. Regarding the etchant, any solution which etches nickel monosilicide little and, on the other hand, easily etches nickel-rich nickel silicide is usable. Such solutions other than the above are, for example, a mixture of sulfuric acid, hydrogen peroxide, and water, and a mixture of ammonia water, hydrogen peroxide, and water. In addition, for promoting the etching reaction and for entirely removing the nickel silicide on the insulator film, for example, methods for changing the mixing ratio of the chemicals, heating the solution, and combining several solutions may be used.

In the fourth embodiment, substrates of a silicon on insulator (SOI) and a silicon-germanium on insulator (SGOI) may be used as well as a usual silicon substrate 81.

In addition, as explained in the third embodiment, a nickel silicide film may be formed by causing the above-described silicide reaction after co-depositing nickel and silicon instead of forming a stacked layer film of a nickel layer and a silicon layer.

Furthermore, as explained in the first embodiment, a preliminary thermal treatment at a low temperature may be conducted before implementing a thermal treatment at the second substrate temperature. In addition, as explained in the fourth embodiment, after conducting etching with self-aligning manner by making use of difference of the film crystallity between the semiconductor region and insulator region after the preliminary thermal treatment at a low temperature, a silicide reaction may be caused by conducting a thermal treatment at the second substrate temperature.

### Fifth Embodiment

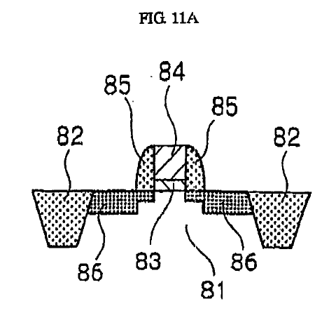

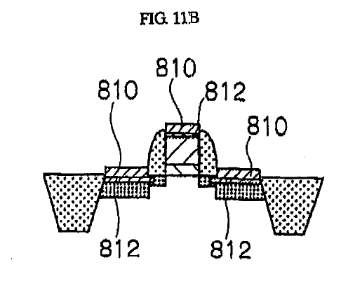

Next, a semiconductor device fabrication method of a fifth embodiment of the present invention will be explained. The fifth embodiment of the present invention is different from the above fourth embodiment regarding a source/drain region and a gate electrode. That is, in the fifth embodiment, the source/drain region and the gate electrode are composed of silicon-germanium mixed crystal and silicon-germanium poly crystal, respectively. FIG. 11A to FIG. 11B are partial traverse cross sectional views showing each process according to one example of method of the fifth embodiment of the present invention for forming a nickel silicide film containing nickel monosilicide as a main composition on the source/drain region and the gate electrode of a MOS transistor on a silicon substrate with a self-aligning manner. Recently, for increasing a performance of a MOS transistor, a use of silicon-germanium mixed crystal for the source/drain region End a use of silicon-germanium poly crystal for the gate electrode have been proposed. The fifth embodiment may also be applicable to these.

In the fifth embodiment, as shown in FIG. 11A, gate electrode 84 is made of silicon-germanium poly crystal and source/drain region 86 is made of silicon-germanium mixed crystal. This is realized through the following processes. For example, in the usual MOS transistor fabrication process, silicon-germanium poly crystal is grown instead of growing poly crystal silicon at the gate electrode formation process, and silicon-germanium mixed crystal is grown through selective epitaxial growth with, for example, CVD after removing a silicon layer once by etching on the source/drain region after the gate electrode formation. Otherwise, it may be possible to deposit silicon-germanium mixed crystal with selective epitaxial growth without etching the source/drain region. In FIG. 11A, symbol 81 is a silicon substrate, symbol 82 is a device isolation region, symbol 83 is a gate insulator film, and symbol 85 is a gate sidewall.

For a structure shown in FIG. 11A, as with the method similar to the fourth embodiment, first, a nickel layer and a silicon layer are alternately deposited at a first substrate temperature. In the above-described fourth embodiment, a deposition temperature was set at less than 200° C., so as to make the silicon layer an amorphous state, and not to react nickel and, silicon and silicon-germanium mixed crystal to each other during the deposition. In this case, as with the fourth embodiment, thicknesses of the nickel layer and the silicon layer are also configured so that a ratio (N_{Ni}/Nₛᵢ) of the number of total nickel atoms (N_{Ni}) to the number of total silicon atoms (Nₛᵢ) existing in the whole stacked layer film becomes equal to or more than 1. However, the thicknesses and the number of layers of the nickel layer and the silicon layer can be varied according to a required thickness of a nickel monosilicide film.

Next, a thermal treatment at the second temperature which is higher than the first temperature is conducted, followed by removing nickel silicide on an insulator film using an etchant similar to the fourth embodiment, then, as shown in FIG. 11B, a structure which is formed nickel monosilicide film 810 on source/drain region 86 and gate electrode 84 is obtained. In this case, since a part of nickel atoms diffuse into silicon-germanium mixed crystal and react with it at gate electrode 84 and source/drain region 86, a nickel germanosilicide (NiSi₁₋ₓGeₓ) layer 812 is formed on gate electrode 84 composed of nickel monosilicide film 810 and the silicon-germanium mixed crystal layer, and source/drain region 86. In the fifth embodiment, it is favorable that the second temperature for the thermal treatment is also less than 750° C. so that nickel monosilicide is well formed and not to cause a disilicide reaction.

According to a conventional method in which only nickel is deposited and thermally treated, the formed film entirely becomes nickel germanosilicide. Also, it is likely to form defects at the interface between the nickel germanosilicide layer and the silicon-germanium mixed crystal layer by germanium precipitation. However, in the present embodiment, through reaction of substantial nickel atoms with the deposited silicon layer, it is possible to make the formed nickel germanosilicide layer 812 extremely thin. A resistivity of nickel germanosilicide increases according to increase in concentration of germanium. A nickel germanosilicide film according to the present embodiment has a lower resistivity than that of the conventional method in which the film is prepared by deposition of only nickel and thermal treatment. In addition, during the thermal treatment, a diffusion of germanium atoms in nickel germanosilicide film takes place, thereby decreasing concentration of germanium atoms in the nickel germanosilicide film, resulting in further lowering of the resistivity.

In the present invention, it is also possible to deposit a silicon layer at the nearest layer to the substrate by reversing the order of deposition of the nickel layer and the silicon layer. This is the same with the fourth embodiment.

As described before, according to the semiconductor device fabrication method of the present invention, it is possible to form a nickel monosilicide film 810 with sufficient thickness, while suppressing silicon-germanium consumption of the substrate even if source drain region 86 and gate electrode 84 are silicon-germanium mixed crystal and poly silicon-germanium, respectively. In addition, in the fifth embodiment, the substrate may be a silicon on insulator (SOI) substrate, or a silicon-germanium on insulator (SGOI) substrate, as well as usual silicon substrate 81.

Further, as explained in the third embodiment, a nickel silicide film may be formed through the silicide reaction after co-depositing nickel and silicon instead of forming a nickel layer and a silicon layer.

Furthermore, as explained in the first embodiment, a preliminary thermal treatment at a low temperature may be implemented before the second substrate temperature. In addition, as explained in the above fourth embodiment, it is possible to cause the silicide reaction by implementing a thermal treatment at the second substrate temperature after etching the substrate with a self-aligning manner using the difference of crystallity on the semiconductor region and the insulator region due to the preliminary thermal treatment at a low temperature.

### Sixth Embodiment

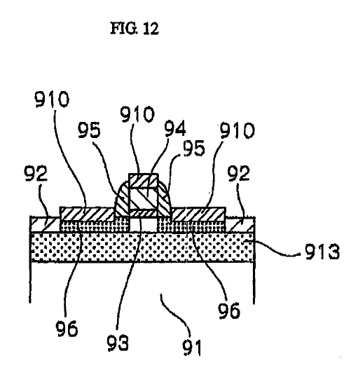

Next, a semiconductor device fabrication method in the sixth embodiment of the present invention will be explained. As an example of the sixth embodiment, the example applying the present invention to a MOS transistor on SOI substrate will be described. FIG. 12 is a partial traverse cross sectional view showing a MOS transistor on a SOI substrate which is formed a nickel silicide film using the sixth embodiment of the present invention with a method similar to the fourth and fifth embodiments. In FIG. 12, the MOS transistor includes silicon substrate 91, device isolation region 92, gate insulator film 93, gate electrode 94 composed of poly crystal silicon, and gate sidewall 95.

In the sixth embodiment, source/drain region 96 is formed in a SOI layer on buried oxide layer 913. In a thin SOI, a thickness of the SOI layer may be about 10 nm. If the present invention is applied, a thick nickel monosilicide film 910 can be formed by suppressing silicon consumption of the SOI layer. For example, if nickel monosilicide film 910 of 20 nm in thickness is formed with a condition that a ratio (N_{Ni}/Nₛᵢ) of the number of total nickel atoms (N_{Ni}) to the number of total silicon atoms (Nₛᵢ) existing in the whole stacked layer film is equal to 1.5 (N_{Ni}:Nₛᵢ=1:0.66), a thickness of the consumed silicon of the SOI layer will be 5 nm, thereby leaving a sufficient distance between the nickel monosilicide film 910 and buried oxide layer 913. In the conventional method in which only nickel is deposited and annealed, if the consumed silicon thickness of the SOI layer is 5 nm, a thickness of the nickel monosilicide film will be about 6 nm. Therefore, a sheet resistance of the conventional film will be more than three times of that of nickel monosilicide film 910 of 20 nm in thickness according to the present invention. Accordingly, in a MOS transistor on the SOI substrate, it is possible to increase performance of the MOS transistor compared with the conventional one, as well as preventing from degrading the MOS transistor performance due to reaching of nickel monosilicide film 910 to the buried oxide layer 913.

In addition, as explained in the third embodiment, a nickel silicide film may be formed through a silicide reaction after co-depositing nickel and silicon instead of forming a stacked layer film of a nickel layer and a silicon layer.

Furthermore, as explained in the first embodiment, a preliminary thermal treatment at a low temperature may be conducted before implementing a thermal treatment at the second substrate temperature. In addition, as explained in the fourth embodiment, after etching the substrate with a self-aligning manner using difference of crystallity of the film between the semiconductor region and the insulator region after the preliminary thermal treatment at a low temperature, the silicide reaction may be caused by conducting a thermal treatment at the second substrate temperature.

### Seventh Embodiment

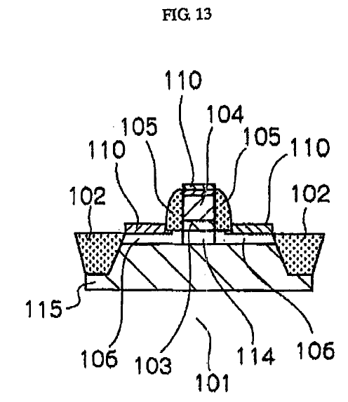

Next, a semiconductor device fabrication method according to a seventh embodiment of the present invention will be explained. The present invention may be applicable to a MOS transistor which uses distorted silicon or distorted silicon-germanium mixed crystal. FIG. 13 is a partial traverse cross sectional view showing a MOS transistor formed on a distorted silicon layer using the seventh embodiment of the present invention with a method similar to that of the above-described fourth to sixth embodiments.

In FIG. 13, silicon-germanium layer 115 is formed on silicon substrate 101, and distorted silicon channel layer 114 and source/drain region 106 are formed on a silicon layer which is formed on silicon-germanium layer 115.

In this structure, a distortion of silicon-germanium in silicon-germanium layer 115 is being relaxed, and the silicon layer which is formed on this layer and containing distorted silicon channel layer 114 and source/drain region 106 is distorted because it is epitaxially grown on silicon-germanium layer 115, of which distortion is relaxed. In a MOS transistor having a distorted silicon channel, the distorted silicon channel 114 must be extremely thin for applying distortion to the silicon layer. A thickness of the silicon layer containing the distorted silicon channel 114 and source/drain region 106 is about 10 nm. Then, if the present invention is applied, as with shown in the sixth embodiment, since it is possible to prevent from reaching of nickel monosilicide film 110 to silicon-germanium layer 115, as well as small silicon consumption of the distorted silicon layer, it becomes possible to prevent from relaxing the distortion of source/drain region 106 and distorted silicon channel region 114 during silicidation of the film.

If nickel monosilicide film 110 reaches to silicon-germanium layer 115, a current leaks through silicon-germanium layer 115. In addition, if the distorted channel region is relaxed, the increase of the MOS transistor performance due to the distorted channel can not be achieved. Then, by applying the present invention to the distorted channel MOS transistor, it becomes possible to prevent from degrading the transistor performance and to sufficiently extract performance of the distorted channel MOS transistor. In FIG. 13, symbol 102 is a device isolation region, symbol 103 is a gate insulator film, symbol 104 is a gate electrode composed of poly crystal silicon, and symbol 105 is a gate sidewall.

In addition, as explained in the third embodiment, a nickel silicide film may be formed through a silicide reaction after co-depositing nickel and silicon instead of forming a stacked layer film of a nickel layer and a silicon layer.

Furthermore, as explained in the first embodiment, a preliminary thermal treatment at a low temperature may be conducted before implementing a thermal treatment at the second substrate temperature. In addition, as explained in the fourth embodiment, after etching the substrate with a self-aligning manner using a difference of crystallity of the film between the semiconductor region and insulator region after the preliminary thermal treatment at a low temperature, the silicide reaction may be caused by conducting a thermal treatment at the second substrate temperature.

### Eighth Embodiment

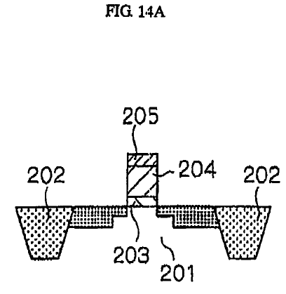

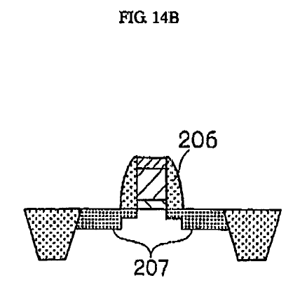

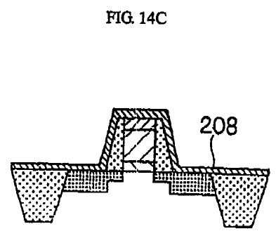

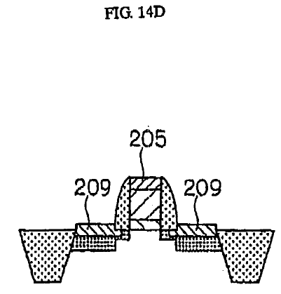

Next, a semiconductor device fabrication method according to the eighth embodiment of the present invention will be explained. It is possible to apply the present invention to a metal gate MOSFET. FIG. 14A to FIG. 14D are partial traverse cross sectional views showing each process according to one example of method of the eighth embodiment of the present invention for forming a nickel silicide film containing nickel monosilicide as a main composition on a source/drain region and a gate electrode of a MOS transistor on a silicon substrate with a self-aligning manner.

First, as shown in FIG. 14A, after depositing gate insulator film 203 and gate electrode (metal) 204 on silicon substrate 201 which is formed device isolation region 202, cap layer 205 composed of a silicon oxide film or a silicon nitride film is formed. After that, a gate structure is fabricated with lithography and dry etching. Regarding cap layer 205, such a film as a silicon oxide film or a silicon nitride film, which does not react with nickel and silicon deposited at later process and is stable against tie etchant during the etching of nickel monosilicide, may be applicable to the film.

Next, after forming a silicon oxide film on the entire substrate, gate sidewall 206 as shown in FIG. 14B is fabricated with dry etching. Cap layer 205 formed in the process shown in FIG. 14A is left on gate electrode 204.

Next, stacked layer film 208 of nickel and silicon shown in FIG. 14C is formed with a method similar to that of the above-described embodiments. After that, as shown in FIG. 14D, nickel monosilicide (NiSi) layer 209 is formed only on source/drain region 207 with etching after annealing. Cap layer 205 on gate electrode 207 is removed by etching when a contact is formed on gate electrode 204.

In addition, as explained in the third embodiment, a nickel silicide film may be formed through a silicide reaction after co-depositing nickel and silicon instead of forming a stacked layer film of a nickel layer and a silicon layer.

Furthermore, as explained in the first embodiment, a preliminary thermal treatment at a low temperature may be conducted before implementing a thermal treatment at the second substrate temperature. In addition, as explained in the fourth embodiment, after etching the substrate with a self-aligning manner using a difference of crystallity of the film between the semiconductor region and insulator region after the preliminary thermal treatment at a low temperature, the silicide reaction may be caused by conducting a thermal treatment at the second substrate temperature.

### Example of Embodiment

The present invention will be further explained specifically below,

An apparatus for molecular beam epitaxy (MBE) was emplyed as a film formation apparatus. After forming a nickel layer first on a silicon single crystal substrate with (100) orientation at a first substrate temperature of 50° C., a silicon layer and a nickel layer were alternately deposited on it, five layers for each in total. After that, in a vacuum atmosphere of the MBE apparatus, a thermal treatment was implemented 30 minutes at the second substrate temperature of 400° C. In Table 1 below, film thicknesses of each nickel layer and silicon layer when they were varied, and sheet resistances of the nickel silicide film obtained after the thermal treatment are shown.

TABLE 1

| | thickness of | thickness of | number of | thermal treatment | |
|---|---|---|---|---|---|
| | Ni layer | Si layer | stacked layer | temperature | sheet resistance |
| sample | (nm) | (nm) | (frequency) | (° C./Centigrade) | (Ω/sq.) |
| A | 2 | 5 | 5 | 400 | 38 |
| B | 2 | 2.5 | 5 | 400 | 9.7 |
| C | 2 | 2 | 5 | 400 | 9.5 |

*) Ω/sq. = Ω/cm²

As described before, when total Si thickness/total Ni thickness is equal to 1.79, a ratio of the number of Ni atoms:the number of Si atoms becomes 1:1 from a calculation using atomic mass and specific gravity of Ni and Si.

As shown in Table 1, in sample A, since thicknesses of the Ni layer and the Si layer are 2 nm and 5 nm, respectively, then, Si thickness/Ni thickness=2.5. Therefore, Si atoms are more than Ni atoms in sample A. In this case, a nickel silicide having favorable nickel monosilicide was not formed, but nickel disilicide having a high sheet resistance was formed.

On the other hand, in sample B, since thicknesses of the Ni layer and the Si layer are 2 nm and 2.5 nm, respectively, then, Si thickness/Ni thickness=1.25. Therefore, Ni atoms are more than Si atoms in sample B. Also, in sample C, since thicknesses of the Ni layer and the Si layer are 2 nm and 2 nm, respectively, then, Si thickness/Ni thickness=1. Therefore, Ni atoms are also more than Si atoms in sample C. In these cases, since nickel monosilicide having a favorable low resistivity has been formed, a low sheet resistance was obtained. In addition, thicknesses of sample B and sample C were measured. Using the thicknesses and the sheet resistances in Table 1, the resistivity was calculated. As a result, it has been found that the resistivity was about 14˜17 μΩcm. From the result of the resistivity data, it has been confirmed that a nickel silicide film composed of favorable nickel monosilicide had been formed. In addition, from results of X-ray diffraction measurement and transmission electron spectroscopy observation, it has been confirmed that favorable nickel monosilicide films were formed in sample B and sample C.

In the present example of the embodiment, for example in sample C, a thickness of nickel silicide film composed of nickel monosilicide was about 18 nm from observation result of transmission electron spectroscopy. In this case, in sample C, silicon atoms corresponding to about 15 nm in film thickness might have been consumed if it is calculated using a consumption factor 0.82. In sample C, a thickness of the total deposited silicon layer was about 10 nm, then, it was supposed that the all silicon atoms had reacted with nickel atoms to form nickel monosilicide. Therefore, silicon atoms of the silicon substrate among the total silicon atoms consumed for the reaction with nickel atoms correspond to 5 nm in thickness. Accordingly, in the present example of the embodiment, it has been confirmed that a nickel silicide film having a sufficient thickness of nickel monosilicide can be formed, while suppressing silicon consumption compared with the conventional method.

These results enable further progress of thinning of the advanced CMOS devices in future. That is, in the advanced CMOS devices, it has been forecasted that a depth of source/drain at contact formation region would become about 20 nm. However, if a conventional method in which nickel is reacted only with a silicon Substrate is used, a thickness of the consumed silicon substrate must be less than half of source/drain depth, that is, less than 10 nm, for not to degrading performance of the transistor. As a result, a thickness of nickel monosilicide becomes less than 12 nm because a consumption factor of nickel monosilicide is 0.82. Therefore, it has been difficult to form a nickel silicide film composed of nickel monosilicide with sufficient thickness for not to degrading junction characteristic and for lowing the resistivity. However, in sample B and sample C of the present examples of the embodiment, as described in the above, since the nickel silicide film composed of nickel monosilicide with sufficient thickness can be formed, it is possible to respond sufficiently to the advanced CMOS devices, and its effect is expectable.

As explained, according to the nickel silicide film formation method and the semiconductor device fabrication method of the present invention, it is possible to provide a method for forming a nickel silicide film having a sufficient thickness and a low resistivity, as well as a low silicon atom consumption of the substrate, thereby possible to achieve high performance of a MOS transistor. In addition, if the present invention is applied to the case in which the substrate surface is a silicon-germanium mixed crystal layer and a poly silicon-germanium layer, a low resistivity film compared with the conventional method, in which only nickel is deposited and reacted, can be obtained as well as low consumptions of silicon atoms and germanium atoms of the substrate. Also, if the present invention is applied to a SOI substrate and a SGOI substrate, a degradation of a MOS transistor performance due to reaching of the nickel silicide film to the buried oxide layer can be prevented.

Further, if the present invention is applied to a distorted channel MOS transistor formed with a semiconductor layer of which surface is formed with a distorted silicon or distorted silicon-germanium layer, a relaxation of the distortion at the channel region during nickel monosilicide formation can be suppressed as well as preventing from reaching of the nickel monosilicide film to the silicon-germanium layer. With the above, a performance degradation of the distorted channel MOS transistor can be prevented and an original performance of the distorted channel MOS transistor can be extracted.

According to the semiconductor device fabrication method of the present invention, since only a nickel silicide film on the insulator film can selectively be etched after causing the silicide reaction of the stacked layer film, a fabrication efficiency of the semiconductor device having a nickel monosilicide film can be increased.

According to the nickel silicide etching method of the present invention, since a nickel-rich nickel silicide film can selectively be etched, an efficient etching process can be achieved.

### POSSIBILITY FOR INDUSTRIAL APPLICATION

The present invention is applicable to any method if the method is related to a method for forming nickel monosilicide with a sufficient thickness and a low resistivity, to a semiconductor fabrication method using the same, and to a method for selectively etching a nickel-rich silicide film of a nickel silicide film, and it has no limitation in the possibility of its application.

While the present invention has been described by associating with some preferred embodiments and examples, it is to be understood that these embodiments and examples are merely for illustrative of the invention by an example, and not restrictive. While it will be obvious to those skilled in the art that various changes and substitutions by equivalent components and techniques are eased upon reading the specification, it is believed obvious that such changes and substitutions fit into the true scope and spirit

What is claimed is:

1. A nickel silicide film formation method, comprising steps of:
a step for forming a layer structure containing silicon and nickel on a substrate at a first substrate temperature which does not cause a silicide reaction; and
a step of the silicide reaction for forming nickel monosilicide by implementing a thermal treatment of the layer structure at a second substrate temperature which causes a nickel monosilicide reaction, wherein, in the step for forming the layer structure, a ratio (N_{Ni}/Nₛᵢ) of a number of total nickel atoms (N_{Ni}) to a number of total silicon atoms (Nₛᵢ) existing in a whole layer structure is equal to or more than 1.

2. A nickel silicide film formation method according to claim 1, wherein the step for forming the layer structure is consist of co-depositing step of nickel and silicon.

3. A nickel silicide film formation method according to claim 1, wherein the step for forming the layer structure is consist of a step alternately forming at least one nickel layer and at least one silicon layer.

4. A nickel silicide film formation method according to claim 3, wherein the layer structure is formed such that a ratio of the number of nickel atoms in each nickel layer contained in the layer structure to the number of silicon atoms in each silicon layer contained in the layer structure is equal to a ratio of the number of total nickel atoms to the number of total silicon atoms existing in a whole layer structure.

5. A nickel silicide film formation method according to claim 1, wherein the ratio (N_{Ni}/Nₛᵢ) of the number of total nickel atoms (N_{Ni}) to the number of total silicon atoms (Nₛᵢ) existing in the whole layer structure is equal to or more than 1, and equal to or less than 4.

6. A nickel silicide film formation method according to claim 1, wherein the nickel silicide contains the nickel monosilicide equal to or more than 50%.

7. A nickel silicide film formation method according to claim 1, wherein a region of at least one semiconductor selected from a group of single crystal silicon, poly crystal silicon, distorted silicon, single crystal silicon-germanium, poly crystal silicon-germanium, and distorted silicon-germanium is included in an uppermost surface of the substrate

8. A nickel silicide film formation method according to claim 1, wherein substrate is any one selected from a group of a silicon substrate, a SOI substrate, and a SGOI substrate.

9. A nickel silicide film formation method according to claim 1, wherein the layer structure formed with the step of forming the layer structure is an amorphous state.

10. A nickel silicide film formation method according to claim 3, wherein each thickness of the silicon layer and the nickel layer formed with the step of forming the layer structure is in a range of 2 nm-10 nm.

11. A nickel silicide film formation method according to claim 1, wherein a surface orientation of a principal surface of the substrate is other than (111) surface.

12. A nickel silicide film formation method according to claim 1, further comprising a step of:
a step for implementing a preliminary thermal treatment at a low temperature lower than the second substrate temperature after the step of forming the layer structure and before the step of the silicide reaction.

13. An etching method for etching a nickel-rich region located on an insulator region of a nickel silicide film which is formed on at least one semiconductor region and at least one insulator region on a substrate and a composition of the nickel silicide film is different between the semiconductor region and the insulator region,
wherein a ratio (N_{Ni}/Nₛᵢ) of a number of nickel atoms (N_{Ni}) to a number of on atoms (Nₛᵢ) in the nickel-rich region is equal to or more than 1.11.

14. An etching method according to claim 13, wherein a region of the nickel silicide film located on the semiconductor region is composed of nickel monosilicide and a region of the nickel silicide film located on the insulator region is composed of nickel-rich nickel silicide.

15. An etching method according to claim 13, wherein the semiconductor region comprises at least one semiconductor selected from a group of single crystal silicon, poly crystal silicon, distorted silicon, single crystal silicon-germanium, poly crystal silicon-germanium, and distorted silicon-germanium.

16. An etching method according to claim 13, wherein the insulator region comprises at least one selected from silicon oxide and silicon nitride.

17. An etching method according to claim 13, wherein the nickel silicide film is formed with a step for forming a stacked layer film by alternately forming at least one nickel layer and at least one silicon layer at a first substrate temperature which does not cause a silicide reaction, and a step of the silicide reaction for implementing a thermal treatment of the stacked layer film at a second substrate temperature which causes a nickel monosilicide reaction.

18. An etching method according to claim 17, wherein the silicon layer formed with the step for forming the stacked layer film is an amorphous state.

19. An etching method according to claim 17, wherein each thickness of the silicon layer and the nickel layer :Formed with the step for forming the stacked layer film is in a range of 2 nm-10 nm.

20. An etching method according to claim 13, wherein the nickel silicide film is formed with a step for co-depositing nickel and silicon, and a step of a silicide reaction for implementing a thermal treatment at a second substrate temperature which causes a nickel monosilicide reaction.

21. An etching method according to claim 13, wherein the substrate is any one selected from a group of a silicon substrate, a SOI substrate, and a SGOI substrate.

22. An etching method according to claim 13, wherein a surface orientation of a principal surface of the substrate is other than (111) surface.

23. An etching method for etching a nickel-rich region located on an insulator region of a nickel silicide film which is formed on at least one semiconductor region and at least one insulator region on a substrate and a composition of the nickel silicide film is different between the semiconductor region and the insulator region, wherein the nickel-rich region has a diffraction peak of Ni₂Si in X-ray diffraction pattern.

24. An etching method according to claim 23, wherein a region of the nickel silicide film located on the semiconductor region is composed of nickel monosilicide and a region of the nickel silicide film located on the insulator region is composed of nickel-rich nickel silicide.

25. An etching method according to claim 23, wherein the semiconductor region comprises at least one semiconductor selected from a group of single crystal silicon, poly crystal silicon, distorted silicon, single crystal silicon-germanium, poly crystal silicon-germanium, and distorted silicon-germanium.

26. An etching method according to claim 23, wherein the insulator region comprises at least one selected from silicon oxide and silicon nitride.

27. An etching method according to claim 23, wherein the nickel silicide film is formed with a step for forming a stacked layer film by alternately forming at least one nickel layer and at least one silicon layer at a fist substrate temperature which does not cause a silicide reaction, and a step of the silicide reaction for implementing a thermal treatment of the stacked layer film at a second substrate temperature which causes a nickel monosilicide reaction.

28. An etching method according to claim 27, wherein the silicon layer formed with the step for forming the stacked layer film is an amorphous state.

29. An etching method according to claim 27, wherein each thickness of the silicon layer and the nickel layer formed with the step for forming the stacked layer film is in a range of 2 nm-10 nm.

30. An etching method according to claim 23, wherein the nickel silicide film is formed with a step for co-depositing nickel and silicon, and a step of a silicide reaction for implementing a thermal treatment at a second substrate temperature which causes a nickel monosilicide reaction.

31. An etching method according to claim 23, wherein the substrate is any one selected from a group of a silicon substrate, a SOI substrate, and a SGOI substrate.

32. An etching method according to claim 23, wherein a surface orientation of a principal surface of the substrate is other than (111) surface.

33. A semiconductor device fabrication method, comprising steps of:
a step for forming a layer structure containing silicon and nickel on at least one semiconductor region and on at least one insulator region on a substrate at a first substrate temperature which does not cause a silicide reaction; and
a step of the silicide reaction for forming a nickel silicide film containing nickel monosilicide, of which composition is different on the semiconductor region and on the insulator region, by implementing a thermal treatment of the layer structure at a second substrate temperature which causes a nickel monosilicide reaction,
wherein, in the step for forming the layer structure, a ratio (N_{Ni}Nₛᵢ) of a number of total nickel atoms (N_{Ni}) to a number of total silicon atoms (Nₛᵢ) existing in a whole layer structure is equal to or more than 1.

34. A semiconductor device fabrication method according to claim 33, wherein nickel silicide located on the semiconductor region after the silicide reaction step is composed of nickel monosilicide and the nickel silicide located on the insulator region after the silicide reaction step is composed of nickel-rich nickel silicide.

35. A semiconductor device fabrication method according to claim 33, further comprising a step of:
an etching step for removing the nickel-rich nickel silicide located on the insulator region of the nickel silicide film by etching, thereby forming the nickel silicide film only on the semiconductor region with a self-aligning manner.

36. A semiconductor device fabrication method according to claim 33, wherein the step for forming the layer structure is consist of co-depositing step of nickel and silicon.

37. A semiconductor device fabrication method according to claim 33, wherein the step for forming the layer structure is consist of alternately forming at least one nickel layer and at least one silicon layer.

38. A semiconductor device fabrication method according to claim 33, wherein the semiconductor region comprises at least one semiconductor selected from a group of single crystal silicon, poly crystal silicon, distorted silicon, single crystal silicon-germanium, poly crystal silicon-germanium, and distorted silicon-germanium.

39. A semiconductor device fabrication method according to claim 33, wherein the insulator region comprises at least one selected from silicon oxide and silicon nitride.

40. A semiconductor device fabrication method according to claim 33, wherein the substrate is any one selected from a group of a silicon substrate, a SOI substrate, and a SGOI substrate.

41. A semiconductor device fabrication method according to claim 33, wherein the layer structure formed with the step for forming the layer structure is an amorphous state.

42. A semiconductor device fabrication method according to claim 37, wherein each thickness of the silicon layer and the nickel layer formed with the step for forming the layer structure is in a range of 2 nm-10 nm.

43. A semiconductor device fabrication method according to claim 33, wherein a surface orientation of a principal surface of the substrate is other than (111) surface.

44. A semiconductor device fabrication method according to claim 33, further comprising a step of:
a step for implementing a preliminary thermal treatment at a low temperature lower than the second substrate temperature after the step for forming the layer structure and before the step of the silicide reaction.

45. A semiconductor device fabrication method according to claim 44, further comprising a step of:
an etching step for etching off only a region closer to an amorphous state having a poor crystallity located on the insulator region of the layer structure before the silicide reaction step and after the preliminary thermal treatment, thereby forming the nickel silicide film only on the semiconductor region with a self-aligning manner by implementing the silicide reaction only for a remained region on the semiconductor region of the layer structure.

46. A nickel silicide formation method, comprising steps of:
a step for forming a layer structure containing silicon and nickel on at least one semiconductor region and at least one insulator region on a substrate; and
a step of a silicide reaction for forming a nickel silicide film having a nickel monosilicide composition on the semiconductor region as well as having a nickel-rich composition on the insulator region by implementing a thermal treatment of the layer structure at a second substrate temperature which causes a nickel monosilicide reaction,
wherein, in a nickel-rich region located on the insulator region of the nickel silicide film, a ratio (N_{Ni}/Nₛᵢ) of a number of nickel atoms (N_{Ni}) to a number of silicon atoms (Nₛᵢ) is equal to or more than 1.11.

47. A nickel silicide formation method according to claim 46, wherein a region of the nickel silicide film located on the semiconductor region is composed of nickel monosilicide and a region of the nickel silicide film located on the insulator region is composed of nickel-rich nickel silicide.

48. A nickel silicide formation method according to claim 46, wherein the step for forming the layer structure is consist of alternately forming at least one nickel layer and at least one silicon layer at a first substrate temperature which does not cause the silicide reaction.

49. A nickel silicide formation method according to claim 48, wherein the silicon layer formed with the step for forming the layer structure is an amorphous state.

50. A nickel silicide formation method according to claim 46, wherein the step for forming the layer structure is consist of co-depositing step of nickel and silicon.

51. A nickel silicide formation method according to claim 46, further comprising a step of:
a step for implementing a preliminary thermal treatment at a low temperature lower than the second substrate temperature after the step for forming the layer structure and before the step of the silicide reaction.

52. A nickel silicide formation method, comprising steps of:
a step for forming a layer structure containing silicon and nickel on at least one semiconductor region and at least one insulator region on a substrate; and
a step of a silicide reaction for forming a nickel silicide film having a nickel monosilicide composition on the semiconductor region as well as having a nickel-rich composition on the insulator region by implementing a thermal treatment of the layer structure at a second substrate temperature which causes a nickel monosilicide reaction,
wherein a nickel-rich region located on the insulator region of the nickel silicide film has a diffraction peak of Ni₂Si in X-ray diffraction pattern.

53. A nickel silicide formation method according to claim 52, wherein a region of the nickel silicide film located on the semiconductor region is composed of nickel monosilicide and a region of the nickel silicide film located on the insulator region is composed of nickel-rich nickel silicide.

54. A nickel silicide formation method according to claim 52, wherein the step for forming the layer structure is consist of alternately forming at least one nickel layer and at least one silicon layer at a first substrate temperature which does not cause the silicide reaction.

55. A nickel silicide formation method according to claim 54, wherein the silicon layer formed with the step for forming the layer structure is an amorphous state.

56. A nickel silicide formation method according to claim 52, wherein the step for forming the layer structure is consist of co-depositing step of nickel and silicon.

57. A nickel silicide formation method according to claim 52, further comprising a step of:
a step for implementing a preliminary thermal treatment at a low temperature lower than the second substrate temperature after the step for forming the layer structure and before the step of the silicide reaction.

58. A nickel silicide formation method, comprising steps of:
a step for forming a stacked layer film by alternately forming at least one nickel layer and at least one silicon layer on a substrate at a first substrate temperature which does not cause a silicide reaction; and
a step of the silicide reaction for forming a nickel silicide film by implementing a thermal treatment of the stacked layer film at a second substrate temperature which causes a nickel monosilicide reaction,
wherein, in the step for forming the stacked layer film a ratio of a total silicon layer thickness to a total nickel layer thickness in the stacked layer film is equal to or less than 1.79.

59. A nickel silicide formation method according to claim 58, wherein the silicon layer formed with the step for forming the stacked layer film is an amorphous state.

60. A semiconductor device fabrication method, comprising steps of:
a step for forming a stacked layer film by alternately forming at least one nickel layer and at least one silicon layer on at least one semiconductor region and on at least one insulator region on a substrate at a first substrate temperature which does not cause a silicide reaction; and
a step of the silicide reaction for forming a nickel silicide film containing nickel monosilicide, of which composition is different on the semiconductor region and on tile insulator region, by implementing a thermal treatment of the stacked layer film at a second substrate temperature which causes nickel monosilicide reaction,
wherein, in the step for forming the stacked layer film, a ratio of a total silicon layer thickness to a total nickel layer thickness in the stacked layer film is equal to or less than 1.79.

61. A semiconductor device fabrication method according to claim 60, further comprising a step of:
an etching step for removing the nickel-rich nickel silicide located on the insulator region of the nickel silicide film by etching, thereby forming the nickel silicide film only on the semiconductor region with a self-aligning manner.

62. A semiconductor device fabrication method according to claim 60, wherein the silicon layer formed with the step for forming the stacked layer film is an amorphous state.

63. A semiconductor device fabrication method, comprising steps of:
a step for forming a layer structure containing silicon and nickel on at least one semiconductor region and at least one insulator region on a substrate at a first substrate temperature which does not cause a silicide reaction;
a step for forming a region having a low crystallity close to an amorphous state located on the insulator region and a region having a high crystallity located on the semiconductor region by implementing a preliminary thermal treatment at a temperature lower than a second substrate temperature;
a step of etching for removing only the region having the low crystallity close to the amorphous state located on the insulator region; and
a step of the silicide reaction for forming a nickel silicide film with a self-aligning manner only on the semiconductor region by implementing a thermal treatment for the high crystallity region remained on the semiconductor region at the second substrate temperature which causes a nickel monosilicide reaction,
wherein, in the step for forming the layer structure, a ratio (N_{Ni}Nₛᵢ) of a number of total nickel atoms (N_{Ni}) to a number of total silicon atoms (Nₛᵢ) existing in a whole layer structure is equal to or more than 1.

64. A semiconductor device fabrication method according to claim 63, wherein the step for forming the layer structure is consist of alternately forming at least one nickel layer and tit least one silicon layer at the first substrate temperature which does not cause the silicide reaction.

65. A semiconductor device fabrication method according to claim 63, wherein the step for forming the layer structure is consist of co-depositing step of nickel and silicon.
